(19) United States
(12) Patent Application Publication
(10) Pub. No.: US 2012/0125414 A1
(43) Pub. Date: May 24, 2012

(54) PHOTOELECTRIC CONVERTER

(75) Inventors: Hisamitsu KAMEZAKI, Kanagawa (JP); Yoshihisa NAIJO, Kanagawa (JP); Tohru YASHIRO, Kanagawa (JP); Tamotsu HORIUCHI, Shizuoka (JP); Masafumi TORII, Kanagawa (JP)

(73) Assignee: RICOH COMPANY, LTD., Tokyo (JP)

(21) Appl. No.: 13/282,757

(22) Filed: Oct. 27, 2011

(30) Foreign Application Priority Data
Nov. 24, 2010 (JP) 2010-261429

(51) Int. Cl. H01L 51/44

(52) U.S. Cl. 136/255

(57) ABSTRACT

The photoelectric converter includes a substrate; and multiple cells located on the substrate so as to be overlaid. The first cell contacted with the substrate includes a transparent electrode located on the substrate, and a first photoelectric conversion layer located on the transparent electrode. The other cell or each of the others of the multiple cells includes a porous electroconductive layer located closer to the substrate and including an electroconductive material, and a photoelectric conversion layer located on the porous electroconductive layer. Each of the photoelectric conversion layers of the multiple cells includes an electron transport layer including an electron transport material, a dye connected with or adsorbed on the electron transport material, and a hole transport material. The hole transport material is also contained in voids of the porous electroconductive layer.

### CROSS-REFERENCE TO RELATED APPLICATIONS

This patent application is based on and claims priority pursuant to 35 U.S.C. §119 to Japanese Patent Application No. 2010-261429, filed on Nov. 24, 2010, in the Japan Patent Office, the entire disclosure of which is hereby incorporated herein by reference.

### FIELD OF THE INVENTION

This disclosure relates to a photoelectric converter. Particularly, this disclosure relates to a layered photoelectric converter, which is layered using an electrode capable of transmitting a hole.

### BACKGROUND OF THE INVENTION

There are several types of solar cells, but almost all the commercialized solar cells are diode type solar cells in which silicone semiconductors are connected. Since these solar cells have high manufacturing costs at the present time, the solar cells are not broadly used.

In attempting to reduce costs of solar cells, Mr. Graetzel of EPL Lausanne in Switzerland et al. propose a dye-sensitized solar cell with a high efficiency as described in a Japanese patent No. 2,664,194, and Nature, 353, pp. 737-740. In addition, Mr. Hara et al. present a paper, “Electron Transport in Coumarin-Dye-Sensitized Nanocrystalline TiO₂ Electrodes” in Journal of Physical Chemistry B, 109, pp. 23776-23778. There is a desire for commercialization of these dye-sensitized solar cells.

The solar cell of Graetzel has a transparent electroconductive glass substrate, and a porous metal oxide semiconductor layer, a dye layer adsorbed n the semiconductor layer, an electrolyte layer having a redox pair, and an opposite electrode. In this solar cell of Graetzel, the photoelectric conversion efficiency is enhanced by increasing the surface area of the semiconductor electrode using a porous titanium oxide as the metal oxide, and by subjecting a dye (ruthenium complex) to a monomolecular adsorption on the metal oxide semiconductor layer.

These solar cells are classified into dye-sensitized solar cells (DSSC), which form one category of batteries. Specific examples of the photosensitizing dyes for use in such DSSC include materials capable of absorbing visible light such as bipyridine complexes, terpyridine complexes, merocyanine dyes, porphyrin, and phthalocyanine.

It has been considered that it is preferable to use only one dye having a high purity for a DSSC in order to enhance the photoelectric conversion efficiency. The reason therefor is considered as follows. Specifically, when plural kinds of dyes are present on a semiconductor layer while mixed, exchange of electrons between the dyes or recombination of electrons and holes is caused, or electrons transferred from a dye to the semiconductor layer are caught by another dye, and thereby the number of electrons sent from the exited photosensitizing dye to the transparent electrode is decreased, resulting in serious decrease of the quantum yield (i.e., a ratio of generated current to absorbed photoelectrons). This is disclosed in the paper of Hara, or papers, “Electron transport process in a dye-sensitized nanocrystalline TiO₂ on which both a ruthenium bipyridine complex and a ruthenium biquinoline complex are adsorbed” by Yanagida et al. in Photochemistry discussion 2005, 2P132, and “Theoretical efficiency of dye-sensitized solar cell” by Uchida in FAQ at http://kuroppe.tangen.tohoku.ac.jp/ dsc/cell.html.

Suitable dyes for use alone in such dye-sensitized solar cells include bipyridine complexes such as cis-bis(isothiocyanato)bis(2,2′-bipyridyl-4,4′-dicarboxylic acid)ruthenium (II) di-tetrabutyl ammonium complex (i.e., N719). Other bipyridine complexes such as cis-bis(isothiocyanato)bis(2,2′-bipyridyl-4,4′-dicarboxylic acid)ruthenium (II) (i.e., N3), and terpyridine complexes such as tris(isthiocyanato)(2,2′:6′,2″-terpyridyl-4,4-dicarboxylic acid)ruthenium (II) tri-tetrabutyl ammonium complex (i.e., Black Dye) can also be used as the dye.

When N3 or Black Dye is used, a coadsorbent can be used. Such a coadsorbent is added to prevent the molecules of a dye from causing association on a semiconductor layer. Specific examples thereof include chenodeoxycholic acid, taurodeoxycholic acid, 1-decrylphosphoric acid, and the like. These coadsorbents have a characteristic such that the molecules thereof have a functional group, which can be easily adsorbed on titanium dioxide constituting the semiconductor layer, such as carboxyl and phosphono groups, while having a sigma bond so as to intervene between molecules of a dye to prevent interference of the dye molecules.

In attempting to efficiently absorb (utilize) incident light and convert the absorbed light to electric energy, a DSSC is proposed which includes a first anode including a first sensitizing dye, and a second anode including a second sensitizing dye located in the vicinity of the first anode while separated therefrom. By using two kinds of dyes having different absorption wavelengths for the first and second sensitizing dyes, it is possible to enhance the conversion efficiency. However, the DSSC has a drawback in that light is absorbed by an intermediate electrode, and therefore the second layer insufficiently generates electricity.

On the other hand, there is a proposal for an electrochromic device (EC) using an intermediate electrode. The difference between the EC and the photoelectric converter of this disclosure will be described later.

For these reasons, the inventors recognized that there is a need for a DSSC having a better photoelectric conversion efficiency.

### BRIEF SUMMARY OF THE INVENTION

As an aspect of this disclosure, a photoelectric converter is provided which includes a substrate, and multiple cells located on the substrate so as to be overlaid. The first cell contacted with the substrate includes a transparent electrode located on the substrate, and a first photoelectric conversion layer located on the transparent electrode. The other cell or each of the others of the multiple cells includes a porous electroconductive layer located closer to the substrate and including an electroconductive material, and a photoelectric conversion layer located on the porous electroconductive layer. Each of the photoelectric conversion layers of the multiple cells includes an electron transport layer including an electron transport material, a dye connected with or adsorbed on the electron transport material, and a hole transport material. The hole transport material is also contained in voids of the porous electroconductive layer.

The aforementioned and other aspects, features and advantages will become apparent upon consideration of the following description of the preferred embodiments taken in conjunction with the accompanying drawings.

### BRIEF DESCRIPTION OF THE SEVERAL VIEWS OF THE DRAWINGS

FIG. 1 is a schematic view roughly illustrating the cross-section of an example of the photoelectric converter of this disclosure;

FIG. 2 is a schematic view illustrating in detail the cross-section of another example of the photoelectric converter of this disclosure;

FIG. 3 is a photograph showing a first intermediate electrode (including ITO) of the photoelectric converter illustrated in FIG. 2;

FIG. 4 is a graph showing relation between photovoltage and photocurrent density of a photoelectric converter of Example 1;

FIG. 5 is a graph showing relation between wavelength of light and IPCE (incident photon to current conversion efficiency) of the photoelectric converter of Example 1; and

FIG. 6 is a schematic view for explaining a way to obtain a power from a photoelectric converter of Example 2.

### DETAILED DESCRIPTION OF THE INVENTION

The photoelectric converter of this disclosure includes a substrate, and multiple photoelectric conversion cells located on the substrate so as to be overlaid. A first photoelectric conversion cell contacted with the substrate includes a transparent electrode located on the substrate, and a photoelectric conversion layer located on the transparent electrode. The other cell or each of the other cells includes an electroconductive layer including an electroconductive material therein while having voids, and a photoelectric conversion layer located on the electroconductive layer so as to be farther from the substrate than the photoelectric conversion layer. Each of the photoelectric conversion layers includes an electron transport layer including an electron transport material, a dye connected with or adsorbed on the electron transport material, and a hole transport material. In addition, the hole transport material is also contained in the voids of the electroconductive layer.

The difference of the photoelectric converter of this disclosure from the above-mentioned electrochromic device (EC) is the following.

1. Since information displayed in an electrochromic device is observed with human eyes, the titanium oxide layer has a thickness of about 1 μm to impart good transparency to the device. In contrast, the thickness of the titanium oxide layer of the photoelectric converter of this disclosure is not less than 3 μm.
2. An electrolyte is contained in an electrochromic device, but a hole transport material is contained in the photoelectric converter of this disclosure.
3. A suspending agent is used for an electrochromic device so that the electrochromic device can display a white background, but such a suspending agent is not used for the photoelectric converter of this disclosure.
4. A photoelectric conversion dye is not used for an electrochromic device.

The structure of the layered photoelectric converter of this disclosure (hereinafter referred to the photoelectric converter) will be described by reference to drawings.

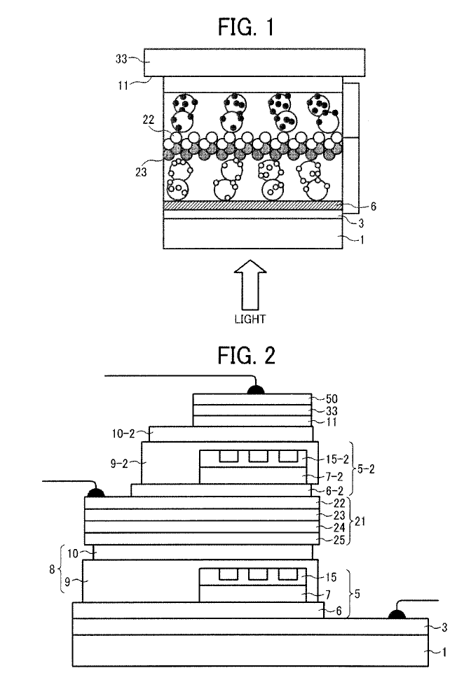

FIG. 1 roughly illustrates the cross-section of an example of the photoelectric converter of this disclosure, and FIG. 2 illustrates in detail the cross-section of the example of the photoelectric converter.

Referring to FIG. 2, the photoelectric converter includes a substrate 1, and an electrode 3 (electron collecting electrode), an electron transport layer 5, which includes a dense electron transport layer 6, a granular electron transport layer 7 and a lattice electron transport layer 15, and a hole transport layer 8, which includes a first hole transport layer 9 including a polymer or an electrolyte and a second hole transport layer 10. These layers are overlaid in this order on the substrate 1. In addition, an intermediate electrode 21 including a second insulating layer 25, a first insulating layer 24, a second intermediate electrode 23, and a first intermediate electrode 22, which are overlaid in this order from the bottom thereof, is located on the hole transport layer 8. Further, another electron transport layer 5-2 having a structure similar to that of the above-mentioned electron transport layer 5 and including a dense electron transport layer 6-2, a granular electron transport layer 7-2 and a lattice electron transport layer 15-2, another first hole transport layer 9-2 having a structure similar to that of the above-mentioned hole transport layer 9, and another second hole transport layer 10-2 having a structure similar to that of the above-mentioned hole transport layer 10 are overlaid on the intermediate electrode 21. Furthermore, a metal oxide layer 11, a second electrode 33, and an opposite substrate 50 are overlaid in this order on the electron transport layer 5-2 and the first hole transport layer 9-2.

The photoelectric converter illustrated in FIG. 2 has a two-layer structure, but the structure of the photoelectric converter of this disclosure is not limited thereto, and it is possible for the photoelectric converter to have a three- or more-layer structure such that one or more of the combination of the intermediate electrode 21, the electron transport layer 5 and the hole transport layer 8 are overlaid in this order.

Initially, the substrate 1 and the electron collecting electrode 3 will be described.

The electron collecting electrode 3 is not particularly limited as long as the electrode is made of a transparent electroconductive material which is transparent to visible light, and any known electrodes for use in general photoelectric converters and liquid crystal panels can be used therefor.

Specific examples of the materials for use as the electroconductive material include indium tin oxide (ITO), fluorine-doped tin oxide (FTO), and the like. Among these materials, FTO is preferably used.

The electron collecting electrode 3 preferably has a thickness of from 5 nm to 100 μm, and more preferably from 50 nm to 10 μm.

Since the electron collecting electrode 3 has to have a certain hardness, it is preferable to provide the electron collecting electrode 3 on the substrate 1 made of a material transparent to visible light. Specific examples of the material for use in the substrate 1 include glass plates, transparent plastic plates, transparent plastic films, crystals of transparent inorganic materials, and the like.

Any known combination materials in which an electron collecting electrode and a substrate are united can be used for the photoelectric converter of this disclosure. Specific examples thereof include FTO-coated glass plates, ITO-coated glass plates, zinc oxide/aluminum-coated glass plates, FTO-coated transparent plastic films, ITO-coated transparent plastic films, and the like.

In addition, transparent electrodes made of tin oxide or indium oxide doped with a cation or anion having a valence different from that of tin or indium, electrodes in which a mesh- or stripe-form metal electrode capable transmitting visible light is located on a transparent substrate such as glass plates, and the like electrodes can also be used for the photoelectric converter of this disclosure. These electrodes can be used alone or in combination.

In order to reduce the resistivity of the substrate 1, a metal lead wire and the like can be used. Specific examples of the metal of the metal lead wire include aluminum, copper, silver, gold, platinum, nickel and the like. Such a metal lead wire is typically formed on a substrate by a method such as vapor deposition, sputtering, and pressing, and then an ITO or FTO layer is formed thereon.

Next, the electron transport layer 5 will be described.

The electron transport layer 5 consisting of a thin semiconductor layer is formed on the above-mentioned electron collecting electrode 3. It is preferable for the electron transport layer 5 to have a structure such that a dense electron transport layer (6) is formed on the electron collecting electrode 3, a porous (granular) electron transport layer (7) is formed thereon, and a lattice electron transport layer (15) is formed thereon.

The dense electron transport layer 6 is formed to prevent electrical contact of the electron collecting electrode 3 with the hole transport layer 8. Therefore, the dense electron transport layer 6 may have a pinhole, a crack and the like as long as the electron collecting electrode 3 is not physically contacted with the hole transport layer 8.

The thickness of the dense electron transport layer 6 is not particularly limited, and is preferably from 10 nm to 1 μm, and more preferably from 20 nm to 700 nm.

The term “dense” of the dense electron transport layer 6 means that the filling bulk density of a particulate inorganic oxide semiconductor therein is higher than the filling bulk density of a particulate semiconductor in the granular (porous) electron transport layer 7.

Next, the lattice electron transport layer 15 will be described.

The lattice electron transport layer 15, which is formed on the dense electron transport layer 6, consists of a single layer or multiple layers. Multi-layer type lattice electron transport layers can be prepared, for example, by a method in which two or more dispersions including respective particulate semiconductors having different particle diameters are coated to overlay two or more layers, a method in which two or more dispersions including different kinds of semiconductors, different kinds of resins, and/or different kinds of additives are coated to overlay two or more layers, or the like method.

When the thickness of the lattice electron transport layer 15 prepared by a single coating method is less than a predetermined thickness, it is preferable to use a multiple coating method.

In general, as the thickness of the electron transport layer increases, the light capturing rate of the layer per a unit area increases because the amount of a photosensitizer included therein increases. However, the diffusion length of electrons injected thereinto also increase, thereby increasing recombination of charges, resulting in deterioration of electron transportability. Therefore, the thickness of the electron transport layer 15 is preferably from 10 nm to 1,000 nm.

Any known masks can be used for forming the lattice of the lattice electron transport layer 15. The lattice is preferably formed of squares with a size of not greater than 1 μm, and more preferably about 20 nm. It is preferable that an electron transport layer is formed in every two square portions of the lattice.

The porous electron transport layer 7 will be described later.

The semiconductor constituting the dense electron transport layer 6 is not particularly limited, and any known semiconductors can be used therefor.

Specific examples thereof include element semiconductors such as silicon and germanium, compound semiconductors such as metal chalcogenide, compounds having a perovskite structure, and the like.

Specific examples of the metal chalcogenide include oxides of metals such as titanium, tin, zinc, tungsten, zirconium, hafnium, strontium, indium, cerium, yttrium, lanthanum, vanadium, niobium, and tantalum; sulfides of metals such as cadmium, zinc, lead, silver, antimony, and bismuth; selenides of metals such as cadmium and lead; tellurides of metals such as cadmium; and the like.

Specific examples of other compound semiconductors include phosphides of metals such as zinc, gallium, indium, and cadmium; gallium arsenide, copper-indium selenide, copper-indium sulfide, and the like.

Specific examples of the compounds having a perovskite structure include strontium titanate, calcium titanate, sodium titanate, barium titanate, potassium niobate, and the like.

These semiconductors can be used alone or in combination. In addition, the crystal form of the semiconductor is not particularly limited, and any crystal forms such as single crystal form, polycrystal form, and amorphous form can be available.

Among these semiconductors, oxide semiconductors are preferable, and titanium oxide, zinc oxide, tin oxide, and niobium oxide are more preferable.

Although the particle size of the particulate semiconductor for use in the dense electron transport layer 6 is not particularly limited, the average primary particle diameter of the particulate semiconductor is preferably from 1 nm to 100 nm, and more preferably from 5 nm to 50 nm.

In addition, a particulate semiconductor having a relatively large average particle diameter of from 50 nm to 500 nm can be added to the particulate semiconductor to scatter incident light, thereby enhancing the photoelectric conversion efficiency

The method for preparing the electron transport layer is not particularly limited, and any known methods such as vacuum thin film forming methods (e.g., sputtering), and wet film forming methods can be used. In view of manufacturing costs, wet film forming methods are preferable. For example, a method including dispersing a powder or sol of a semiconductor in a medium to prepare a paste of the semiconductor, and then applying the paste on an electron collecting electrode formed on a substrate using a known coating method such as dip coating, spray coating, wire bar coating, spin coating, roller coating, blade coating, and gravure coating, or a known printing method such as relief printing, offset printing, gravure printing, intaglio printing, rubber plate printing, and screen printing.

When a mechanical pulverization method or a method using a mill is used for preparing the semiconductor dispersion, a method in which at first a particulate semiconductor is fed in a solvent optionally together with a resin, and the mixture is dispersed by a dispersing machine such as mills can be used.

Specific examples of the resin optionally used for preparing the dispersion include homopolymers or copolymers of vinyl compounds such as styrene, vinyl acetate, acylates, and methacrylates; silicone resins, phenoxy resins, polysulfone resins, polyvinyl butyral resins, polyvinyl formal resins, polyester resins, cellulose ester resins, cellulose ether resins, urethane resins, phenolic resins, epoxy resins, polycarbonate resins, polyarylate resins, polyamide resins, polyimide resins, and the like resins.

Specific examples of the solvent used for preparing the dispersion include water; alcohols such as methanol, ethanol, isopropyl alcohol, and α-terpineol; ketones such as acetone, methyl ethyl ketone, and methyl isobutyl ketone; esters such as ethyl formate, ethyl acetate, and n-butyl acetate; ethers such as diethyl ether, dimethoxy methane, tetrahydrofuran, dioxyolan, and dioxane; amides such as N,N-dimethylformamide, N,N-dimethylacetamide, and N-methyl-2-pyrrolidone; halogenated hydrocarbons such as dichloromethane, chloroform, bromoform, methyl iodide, dichloroethane, trichloroethane, trichloroethylene, chlorobenzene, o-dichlorobenzene, fluorobenzene, bromobenzene, iodobenzene, and 1-chloronaphthalene; hydrocarbons such as n-pentane, n-hexane, n-octane, 1,5-hexadiene, cyclohexane, methylcyclohexane, cyclohexadiene, benzene, toluene, o-xylene, m-xylene, p-xylene, ethyl benzene, and cumene; and the like. These solvents can be used alone or in combination.

The thus prepared semiconductor dispersion (or the paste) can include an additive to prevent agglomeration of the dispersed semiconductor particles. Suitable materials for use as the additive include acids such as hydrochloric acid, nitric acid and acetic acid; surfactants such as polyoxyethylene (10) octylphenyl ether; cheletors such as acetylacetone, 2-aminoethanol, and ethylenediamine; and the like.

In addition, a thickener can be added to the dispersion to improve the film formability of the dispersion. Specific examples thereof include polymers such as polyethylene glycol and polyvinyl alcohol, cellulose derivatives such as ethyl cellulose, and the like.

The thus coated semiconductor dispersion is preferably subjected to a treatment such as sintering, irradiation of microwaves, electron beams or laser, and pressing to electrically contact particles of the semiconductor with each other, to improve the mechanical strength of the film, and to improve the adhesion of the film to the substrate. These treatments can be performed alone or in combination.

When sintering is performed, the temperature is not particularly limited. However, when the temperature is too high, problems such that the resistance of the substrate seriously increases, and the substrate is melted occur. Therefore, the temperature is preferably from 30° C. to 700° C., and more preferably from 100° C. to 600° C. The sintering time is not particularly limited, but is preferably from 10 minutes to 10 hours.

After the sintering treatment, the semiconductor may be subjected to another treatment such as chemical plating using an aqueous solution or a water/organic solvent solution of titanium tetrachloride, or an electrochemical plating using an aqueous solution of titanium trichloride, to increase the surface area of the particulate semiconductor and to enhance the efficiency of electron injection from a photosensitizer to the particulate semiconductor.

When microwave irradiation is performed, the surface to be irradiated with microwaves is not particularly limited, namely microwaves may irradiate the electron transport layer or the backside thereof. The irradiation time is not also particularly limited, but is preferably not longer than 1 hour.

The pressing treatment is preferably performed at a pressure of not less than 100 kg/cm², and more preferably not less than 1,000 kg/cm². The pressing time is not also particularly limited, but is preferably not longer than 1 hour. In addition, the pressing treatment may be performed while heating the semiconductor.

A layer of a particulate semiconductor having a diameter of tens of nanometers, which is prepared by a sintering method or the like, achieves a porous state. The particulate semiconductor layer in such a porous state has a very high surface area, and the surface area is represented using a roughness factor. The roughness factor is defined as a ratio (RA/A) of the real area (RA) of the surface of the semiconductor including the area of inner surfaces of voids of the semiconductor to the surface area (A) of a particulate semiconductor formed on a substrate. Therefore, the roughness factor is preferably as large as possible. However, there is a restriction on the thickness of the electron transport layer, the semiconductor in the electron transport layer of the photoelectric converter of this disclosure preferably has a roughness factor of not less than 20.

Next, the granular (porous)electron transport layer 7 will be described.

The porous electron transport layer 7 is overlaid on the electron transport layer mentioned above. The porous electron transport layer 7 is in a porous state and may be constituted of a single layer or multiple layers.

A multi-layer type porous electron transport layer can be prepared, for example, by a method in which two or more dispersions including respective particulate semiconductors having different particle diameters are coated to overlay two or more layers, a method in which two or more dispersions including different kinds of semiconductors, different kinds of resins, and/or different kinds of additives are coated to overlay two or more layers, and the like method.

When the thickness of the porous electron transport layer 7 prepared by a single-layer coating method is less than a predetermined thickness, it is preferable to use a multiple-layer coating method.

In general, as the thickness of the electron transport layer increases, the light capturing rate of the layer per a unit area increases because the amount of a photosensitizer included therein increases. However, the diffusion length of electrons injected thereinto also increase, thereby increasing recombination of charges, resulting in deterioration of electron transportability. Therefore, the thickness of the porous electron transport layer 7 is preferably from 100 nm to 100 μm.

The semiconductor constituting the porous electron transport layer 7 is not particularly limited, and any known semiconductors can be used therefor.

Specific examples thereof include element semiconductors such as silicon and germanium, compound semiconductors such as metal chalcogenide, compounds having a perovskite structure, and the like.

Specific examples of the metal chalcogenide include oxides of metals such as titanium, tin, zinc, tungsten, zirconium, hafnium, strontium, indium, cerium, yttrium, lanthanum, vanadium, niobium, and tantalum; sulfides of metals such as cadmium, zinc, lead, silver, antimony, and bismuth; selenides of metals such as cadmium and lead; tellurides of metals such as cadmium; and the like.

Specific examples of other compound semiconductors include phosphides of metals such as zinc, gallium, indium, and cadmium; gallium arsenide, copper-indium selenide, copper-indium sulfide, and the like.

Specific examples of the compounds having a perovskite structure include strontium titanate, calcium titanate, sodium titanate, barium titanate, potassium niobate, and the like.

These semiconductors can be used alone or in combination. In addition, the crystal form of the semiconductor is not particularly limited, and any crystal forms such as single crystal form, polycrystal form, and amorphous form can be available.

Among these semiconductors, oxide semiconductors are preferable, and titanium oxide, zinc oxide, tin oxide, and niobium oxide are more preferable.

The particle size of the particulate semiconductor included in the porous electron transport layer 7 is not particularly limited, but the average primary particle diameter of the particulate semiconductor is preferably from 1 nm to 100 nm, and more preferably from 5 nm to 50 nm.

In addition, a particulate semiconductor having a relatively large average particle diameter of from 50 nm to 500 nm can be added to the particulate semiconductor to scatter incident light, thereby enhancing the photoelectric conversion efficiency.

The method for preparing the porous electron transport layer 7 is not particularly limited, and any known methods such as vacuum thin film forming methods (e.g., sputtering), and wet film forming methods can be used. In view of manufacturing costs, wet film forming methods are preferable. For example, a method including dispersing a powder or sol of a semiconductor in a medium to prepare a paste of the semiconductor, and then applying the paste on the dense electron transport layer 6 using a known coating method such as dip coating, spray coating, wire bar coating, spin coating, roller coating, blade coating, and gravure coating, or a known printing method such as relief printing, offset printing, gravure printing, intaglio printing, rubber plate printing, and screen printing.

When a mechanical pulverization method or a method using a mill is used for preparing the semiconductor dispersion, a method in which at first a particulate semiconductor is fed in a solvent optionally together with a resin, and the mixture is dispersed by a dispersing machine such as mills can be used.

Specific examples of the resin optionally used for preparing the dispersion include homopolymers or copolymers of vinyl compounds such as styrene, vinyl acetate, acylates, and methacrylates; silicone resins, phenoxy resins, polysulfone resins, polyvinyl butyral resins, polyvinyl formal resins, polyester resins, cellulose ester resins, cellulose ether resins, urethane resins, phenolic resins, epoxy resins, polycarbonate resins, polyarylate resins, polyamide resins, polyimide resins, and the like resins.

Specific examples of the solvent used for preparing the dispersion include water; alcohols such as methanol, ethanol, isopropyl alcohol, and α-terpineol; ketones such as acetone, methyl ethyl ketone, and methyl isobutyl ketone; esters such as ethyl formate, ethyl acetate, and n-butyl acetate; ethers such as diethyl ether, dimethoxy methane, tetrahydrofuran, dioxyolan, and dioxane; amides such as N,N-dimethylformamide, N,N-dimethylacetamide, and N-methyl-2-pyrrolidone; halogenated hydrocarbons such as dichloromethane, chloroform, bromoform, methyl iodide, dichloroethane, trichloroethane, trichloroethylene, chlorobenzene, o-dichlorobenzene, fluorobenzene, bromobenzene, iodobenzene, and 1-chloronaphthalene; hydrocarbons such as n-pentane, n-hexane, n-octane, 1,5-hexadiene, cyclohexadiene, cyclohexane, methylcyclohexane, cyclohexadiene, benzene, toluene, o-xylene, m-xylene, p-xylene, ethyl benzene, and cumene; and the like. These solvents can be used alone or in combination.

The thus prepared semiconductor dispersion (or the paste) can include an additive to prevent agglomeration of the dispersed semiconductor particles. Suitable materials for use as the additive include acids such as hydrochloric acid, nitric acid and acetic acid; surfactants such as polyoxyethylene (10) octylphenyl ether; cheletors such as acetylacetone, 2-aminoethanol, and ethylenediamine; and the like.

In addition, a thickener can be added to the dispersion to improve the film formability of the dispersion. Specific examples thereof include polymers such as polyethylene glycol and polyvinyl alcohol, cellulose derivatives such as ethyl cellulose, and the like.

The thus coated semiconductor dispersion is preferably subjected to a treatment such as sintering, irradiation of microwaves, electron beams or laser, and pressing to electrically contact particles of the semiconductor with each other, to improve the mechanical strength of the film, and to improve the adhesion of the film to the substrate. These treatments can be performed alone or in combination.

When sintering is performed, the temperature is not particularly limited. However, when the temperature is too high, problems such that the resistance of the substrate seriously increases, and the substrate is melted occur. Therefore, the temperature is preferably from 30° C. to 700° C., and more preferably from 100° C. to 600° C. The sintering time is not particularly limited, but is preferably from 10 minutes to 10 hours.

After the sintering treatment, the semiconductor may be subjected to another treatment such as chemical plating using an aqueous solution or a water/organic solvent solution of titanium tetrachloride, or an electrochemical plating using an aqueous solution of titanium trichloride, to increase the surface area of the particulate semiconductor and to enhance the efficiency of electron injection from a photosensitizer to the particulate semiconductor.

When microwave irradiation is performed, the surface to be irradiated with microwaves is not particularly limited, namely microwaves may irradiate the electron transport layer or the backside thereof. The irradiation time is not also particularly limited, but is preferably not longer than 1 hour.

The pressing treatment is preferably performed at a pressure of not less than 100 kg/cm², and more preferably not less than 1,000 kg/cm². The pressing time is not also particularly limited, but is preferably not longer than 1 hour. In addition, the pressing treatment may be performed while heating the semiconductor.

A layer of a particulate semiconductor having a diameter of tens of nanometers, which is prepared by a sintering method or the like, achieves a porous state. The particulate semiconductor layer in such a porous state has a very high surface area, and the surface area is represented using a roughness factor. The roughness factor is defined as a ratio (RA/A) of the real area (RA) of the surface of the semiconductor including the area of inner surfaces of voids of the semiconductor to the surface area (A) of a particulate semiconductor applied on a substrate. Therefore, the roughness factor is preferably as large as possible. However, there is a restriction on the thickness of the porous electron transport layer, the semiconductor in the electron transport layer of the photoelectric converter of this disclosure preferably has a roughness factor of not less than 20.

In a case where both the dense electron transport layer 6 and the porous electron transport layer are constituted of TiO₂, the layers can be prepared by using different preparation methods. For example, the dense electron transport layer can be prepared by spin-coating a coating liquid having a relatively low viscosity. In contrast, when the porous electron transport layer is prepared, initially a coating liquid including at least a semiconductor and a binder is applied by a printing method to form a film, and the film is heated to evaporate the binder, thereby forming voids in the film, resulting in formation of a porous electron transport layer.

In order to enhance the photoelectric conversion efficiency, it is preferable to adsorb a photosensitization compound on the surface of the porous electron transport layer 7. The photosensitization compound is not particularly limited as long as the compound is optically activated by exciting light. Specific examples of the materials for use as the photosensitization compound include the following compounds.

Metal complex compounds disclosed in a published unexamined Japanese patent application (Kohyo) No. 07-500630 (corresponding to U.S. Pat. No. 5,463,057), and published unexamined Japanese patent applications Nos. 10-233238, 2000-26487, 2000-323191, and 2001-59062.

Coumarin compounds disclosed in published unexamined Japanese patent applications Nos. 10-93118, 2002-164089, and 2004-95450, and J. Phys. Chem. C, 7224, Vol. 111 (2007).

Polyene compounds disclosed in a published unexamined Japanese patent application No. 2004-95450, and Chem. Commun., 4887 (2007).

Indoline compounds disclosed in published unexamined Japanese patent applications Nos. 2003-264010, 2004-63274, 2004-115636, 2004-200068 and 2004-235052, and J. Am. Chem. Soc., 12218, Vo. 126 (2004), Chem. Commun., 3036 (2003), and Angew. Chem. Int. Ed., 1923, Vol. 47 (2008).

Thiophene compounds disclosed in J. Am. Chem. Soc., 16701, Vo. 128 (2006), and J. Am. Chem. Soc., 14256, Vo. 128 (2006).

Cyanine dyes disclosed in published unexamined Japanese patent applications Nos. 11-86916, 11-214730, 2000-106224, 2001-76773 and 2003-7359.

Merocyanine dyes disclosed in published unexamined Japanese patent applications Nos. 11-214731, 11-238905, 2001-52766, 2001-76775 and 2003-7360.

9-Arylxanthene compounds disclosed in published unexamined Japanese patent applications Nos. 10-92477, 11-273754, 11-273755 and 2003-31273.

Triarylmethane compounds disclosed in published unexamined Japanese patent applications Nos. 10-93118 and 2003-31273.

Phthalocyanine compounds and porphyrin compounds disclosed in published unexamined Japanese patent applications Nos. 09-199744, 10-233238. 11-204821, 11-265738 and 2006-32260, and J. Phys. Chem., 2342, Vol. 91 (1987), J. Phys. Chem., B, 6272, Vol. 97 (1993), Electroanal. Chem., 31, Vol. 537 (2002), J. Porphyrins Phthalocyanines, 230, Vol. 3 (1999), Angew. Chem. Int. Ed., 373, Vol. 46 (2007), and Langmuir, 5436, Vol. 24 (2008).

Among these compounds, metal complex compounds, coumarin compounds, polyene compounds, indoline compounds and thiophene compounds are preferably used.

Among these compounds, dyes having the following formula (1) or (2) are more preferable.

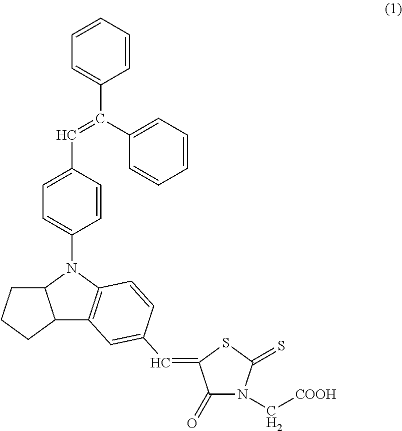

Rational formula of the compound (1): C₃₇H₃₀N₂O₃S₂
Exact mass of the compound (1): 614.17
Molecular weight of the compound (1): 614.78
Weight ratio of elements: C72.29 H4.92 N4.56 O7.81 S10.43

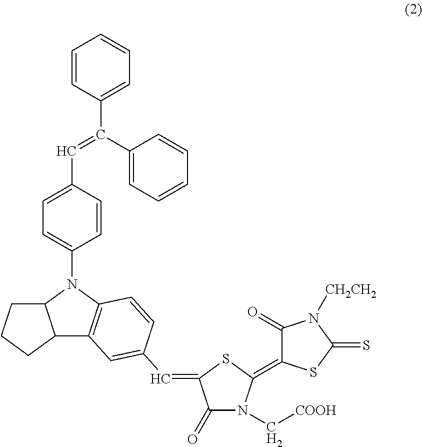

Rational formula of the compound (2): C₄₂H₃₅N₃O₄S₃
Exact mass of the compound (2): 714.18
Molecular weight of the compound (2): 741.94
Weight ratio of elements: C67.99 H4.75 N5.66 O8.63 512.97

In order to adsorb a photosenstization compound on the surface of the porous electron transport layer 7, a method in which the porous electron transport layer formed on the electron collecting electrode with the dense electron transport layer 6 therebetween is dipped into a solution or dispersion of a photosenstization compound; a method in which a solution or dispersion of a photosenstization compound is applied on the surface of the porous electron transport layer; or the like method can be used.

Dip coating methods, roller coating methods, air knife coating methods and the like can be used for the first-mentioned method, and wire bar coating methods, slide hopper coating methods, extrusion coating methods, curtain coating methods, spin coating methods, spray coating methods and the like can be used for the second-mentioned method.

In addition, it is possible to adsorb a photosenstization compound on the surface of the porous electron transport layer in a supercritical fluid.

When a photosenstization compound is adsorbed on the surface of the porous electron transport layer, a condensing agent can be used.

Suitable condensing agents include agents which connect physically or chemically a photosenstization compound with the surface of an inorganic material so as to serve as a catalyst; agents which affect stoichiometrically a photosenstization compound and an inorganic material to advantageously change the chemical equilibrium; and the like.

In addition, condensing auxiliaries such as thiols and hydroxyl compounds can be used.

Specific examples of the solvent for use in preparing a solution or dispersion of a photosensitization compound include water; alcohols such as methanol, ethanol, and isopropyl alcohol; ketones such as acetone, methyl ethyl ketone, and methyl isobutyl ketone; esters such as ethyl formate, ethyl acetate, and n-butyl acetate; ethers such as diethyl ether, dimethoxy methane, tetrahydrofuran, dioxyolan, and dioxane; amides such as N,N-dimethylformamide, N,N-dimethylacetamide, and N-methyl-2-pyrrolidone; halogenated hydrocarbons such as dichloromethane, chloroform, bromoform, methyl iodide, dichloroethane, trichloroethane, trichloroethylene, chlorobenzene, o-dichlorobenzene, fluorobenzene, bromobenzene, iodobenzene, and 1-chloronaphthalene; hydrocarbons such as n-pentane, n-hexane, n-octane, 1,5-hexadiene, cyclohexane, methylcyclohexane, cyclohexadiene, benzene, toluene, o-xylene, m-xylene, p-xylene, ethyl benzene, and cumene; and the like. These solvents can be used alone or in combination.

When two or more photosensitization compounds are adsorbed, there is a case where the compounds cause agglomeration depending on the properties of the compounds. In order to prevent such agglomeration, a dissociation agent can be used. Specific examples of such a dissociation agent include steroid compounds such as cholic acid and chenodeoxycholic acid, long chain alkylcarboxylic acids, long chain alkylphosphoric acids, and the like. The added amount of such a dissociation agent is preferably from 0.01 to 500 parts by weight, and more preferably from 0.1 to 100 parts by weight, per 100 parts by weight of the photosensitization compound used.

When a photosensitization compound or a combination of a photosensitization compound and a dissociation agent is adsorbed on the surface of the porous electron transport layer, the temperature is preferably from −50° C. to 200° C. In addition, the adsorption treatment is preferably performed in a dark place.

The adsorption treatment is performed while the coating liquid is allowed to settle or agitated. The agitation is performed by an agitator such as stirrers, ball mills, paint conditioners, sand mills, attritors, dispersers, supersonic dispersing machines, and the like.

The adsorption time is preferably from 5 seconds to 1,000 hours, more preferably from 10 seconds to 500 hours, and even more preferably from 1 minute to 150 hours.

Next, the hole transport layer 8 will be described.

The hole transport layer 8 has a structure such that different hole transport layers (i.e., the first hole transport layer 9 and the second hole transport layer 10) are overlaid. The second hole transport layer 10, which is closer to the second electrode 33, includes a polymer.

By using a polymer having good film formability, the surface of the porous electron transport layer can be smoothed, thereby enhancing the photoelectric conversion efficiency of the photoelectric converter.

In addition, since it is hard for a polymer included in the second hole transport layer 10 to penetrate into the porous electron transport layer 7, the porous electron transport layer can be well covered with the polymer, thereby producing an effect such that occurrence of short circuit is prevented when the electrode is formed, resulting in enhancement of the performance of the resultant photoelectric converter.

Known hole transport materials can be used for the second hole transport layer 10 which is closer to the second electrode 33. Specific examples thereof include oxadiazole compounds disclosed in a published examined Japanese patent application No. 34-5466, triphenylmethane compounds disclosed in a published examined Japanese patent application No. 45-555, pyrazoline compounds disclosed in a published examined Japanese patent application No. 52-4188, hydrazone compounds disclosed in a published examined Japanese patent application No. 55-42380, oxadiazole compounds disclosed in a published unexamined Japanese patent application No. 56-123544, tetraarylbenzidine compounds disclosed in a published unexamined Japanese patent application No. 54-58445, and stilbene compounds disclosed in a published unexamined Japanese patent applications Nos. 58-65440 and 60-98437.

Known hole transport polymers can be used for the second hole transport layer 10. Specific examples thereof include polythiophene compounds such as poly(3-n-hexylthiophene), poly(3-n-octyloxythiophene), poly(9,9′-dioctyl-fluorene-co-bithiophene), poly(3,3′″-didodecyl-quarterthiophene), poly(3,6-dioctylthieno[3,2-b]thiophene), poly(2,5-bis(3-decylthiophene-2-yl)thieno[3,2-b]thiophene), poly(3,4-didecylthiophene-co-thieno[3,2-b]thiophene), poly(3,6-dioctylthieno[3,2-b]thiophene-co-thieno[3,2-b]thiophene), poly(3,6-dioctylthieno[3,2-b]thiophene-co-thiophene), and poly(3,6-dioctylthieno[3,2-b]thiophene-co-bithiophene); polyvinylenephenylene compounds such as poly[2-methoxy-5-(2-ethylhexyloxy)-1,4-phenylenevinylene], poly[2-methoxy-5-(3,7-dimethyloctyloxy)-1,4-phenylenevinylene], and poly[(2-methoxy-5-(2-ethylhexyloxy)-1,4-phenylenevinylene)-co-(4,4′-biphenylene-vinylene); polyfluorene compounds such as poly(9,9′-didodecylfluorenyl-2,7-diyl), poly[(9,9-dioctyl-2,7-divinylenefluorene)-alt-co-(9,10-anthracene)], poly[(9,9-dioctyl-2,7-divinylenefluorene)-alt-co-(4,4′-biphenylene)], poly[(9,9-dioctyl-2,7-divinylenefluorene)-alt-co-(2-methoxy-5-(2-ethylhexyloxy)-1,4-phenylene), and poly[(9,9-dioctyl-2,7-diyl)-co-(1,4-(2,5-dihexyloxy)benzene)]; polyphenylene compounds such as poly[2,5-d]octyloxy-1,4-phenylene], and poly[2,5-di(2-ethylhexyloxy)-1,4-phenylene]; polyarylamine compounds such as poly[(9.9-dioctylfluorenyl-2,7-diyl)-alt-co-(N,N′-diphenyl)-N,N′-di(p-hexylphenyl-1,4-diaminobenzene], poly[(9.9-dioctylfluorenyl-2,7-diyl)-alt-co-(N,N′-bis(4-octyloxyphenyl)benzidine-N,N′-(1,4-diphenylene)], poly[N,N′-bis(4-octyloxyphenyl)benzidine-N,N′-(1,4-diphenylene)], poly[(N,N′-bis(4-(2-ethylhexyloxy)phenyl)benzidine-N,N′-(1,4-diphenylene)], poly[phenylimino-1,4-phenylenevinylene-2,5-dioctyloxy-1,4-phenylenevinylene-1,4-phenylene, poly[p-tolylimino-1,4-phenylenevinylene-2,5-di(2-ethylhexyloxy)-1,4-phenylenevinylene-1,4-phenylene], and poly[4-(2-ethylhexyloxy)phenylimino-1,4-biphenylene]; and polythiadiazole compounds such as poly[(9,9-dioctylfluorenyl-2,7-diyl)]alt-co-(1,4-benzo(2,1′,3)thiadiazole)], and poly[3,4-didecylthiophene-co-(1,4-benzo(2,1′,3)thiadiazole)].

Among these compounds, polythiophene compounds and polyarylamine compounds are preferable because of having a good combination of carrier mobility and ionization potential.

The hole transport layer can include an additive.

Specific examples of such an additive include iodine, metal iodides such as lithium iodide, sodium iodide, potassium iodide, cesium iodide, calcium iodide, copper iodide, iron iodide, and silver iodide, iodides of quaternary ammonium compounds such as tetraalkyl ammonium iodide, and pyridinium iodide, metal bromides such as lithium bromide, sodium bromide, potassium bromide, cesium bromide, and calcium bromide, bromides of quaternary ammonium compounds such as tetraalkyl ammonium bromide, and pyridinium bromide, metal chlorides such as copper chloride, and silver chloride, metal acetates such as copper acetate, silver acetate, and palladium acetate, metal sulfates such as copper sulfate, and zinc sulfate, metal complexes such as ferrocyanic acid salt-ferricyanic acid salt, ferrocene-ferricinium ion, sulfur compounds such as sodium polysulfide, viologen dyes, hydroquinone, and alkylthiol-alkyldisulfide, ionic liquids described in Inorg. Chem. 35 (1996) 1168 such as 1,2-dimethyl-3-n-propylimidazolinium iodide, salts of 1,2-dimethyl-3-ethylimidazoliumtrifluoromethanesulfonic acid, salts of 1-methyl-3-butylimidazoliumnonafluorobutylsulfonic acid, and 1-methyl-3-ethylimidazoliumbis(trifluoromethylsulfonyl)imide, basic compounds such as pyridine, 4-t-butylpyridine, and benzimidazole, and lithium compounds such as lithium trifluoromethanesulfonylimide, and lithium diisopropylimide.

In addition, in order to enhance the electroconductivity of the hole transport layer, oxidizers capable of changing some of molecules of a hole transport compound into a radical cation can be included in the hole transport layer. Specific examples thereof include tris(4-bromophenyl)aluminum hexachloroantimonate, silver hexachloroantimonate, and nitrosoniumtetrafluoroborate.

It is not necessary to oxidize all of molecules of the hole transport material included in the hole transport layer, and it is acceptable that some of molecules of the hole transport material are oxidized. The added oxidizer may be included in the hole transport layer or removed therefrom.

The hole transport layer 8 is formed on the electron transport layer 7, which bears a photosensitization compound and which is covered with a photosensitization compound layer, so as to cover the electron transport layer. By thus forming the hole transport layer 8, the layer is evenly adsorbed on and connected with the electron transport layer 7. In this regard, the hole transport layer 8 is physically adsorbed on the electron transport layer 7 while the photosensitization compound is chemically adsorbed on the electron transport layer.

The method for preparing the hole transport layer 8 is not particularly limited, and any known methods such as vacuum thin film forming methods (e.g., sputtering), and wet film forming methods can be used. In view of manufacturing costs, wet film forming methods are preferable. When a wet film forming method is used, any known coating methods such as dip coating, spray coating, wire bar coating, spin coating, roller coating, blade coating, and gravure coating, or any known printing methods such as relief printing, offset printing, gravure printing, intaglio printing, rubber plate printing, and screen printing can be used.

It is possible to inject a hole transport material using a supercritical fluid or a subcritical fluid.

A supercritical fluid is defined as a material which is present as a noncondensable high density fluid under temperature/pressure conditions higher than the critical point thereof below which the material can have both a gas state and a liquid state at the same time. Even when such a supercritical fluid is pressed, the supercritical fluid is not aggregated (condensed). Any known supercritical fluids can be used for this application. Among these supercritical fluids, supercritical fluids having a low critical temperature and a low critical pressure are preferably used for this application.

Specific examples of the materials for use as the supercritical fluid in this application include carbon monoxide, carbon dioxide, ammonia, nitrogen, water, alcohols (e.g., methanol, ethanol, and n-butanol), hydrocarbons (e.g., ethane, propane, 2,3-dimethylbutane, benzene, and toluene), halogenated hydrocarbons (e.g., methylene chloride, and chlorotrifluoromethane), ethers (e.g., dimethyl ether), and the like. These materials can be used alone or in combination. Among these materials, carbon dioxide is preferably used because of having a critical temperature (31° C.) near room temperature and a critical pressure (7.3 MPa) near normal pressure. Therefore, carbon dioxide can be easily changed to a supercritical state. In addition, carbon dioxide is highly safe because of being nonflammable. When supercritical carbon dioxide is present under normal temperature and normal pressure conditions, it becomes a gas. Therefore, carbon dioxide can be easily collected and reused.

A sub-critical fluid is defined as a material which is present as a high pressure liquid under a temperature/pressure condition in the vicinity of the critical point of the material. Any known sub-critical fluids can be used for this application. The materials mentioned above for use as the supercritical fluids can also be used as sub-critical fluids.

The critical temperature and critical pressure are not particularly limited. The critical temperature is preferably from −273° C. to 300° C. and more preferably from 0° C. to 200° C.

When the hole transport layer is prepared by using a supercritical fluid or a sub-critical fluid, an organic solvent or an entrainer can be added thereto to adjust the solubility of a hole transport material in the fluid.

Any known solvents and entrainers can be used. Specific examples thereof include ketones such as acetone, methyl ethyl ketone, and methyl isobutyl ketone; esters such as ethyl formate, ethyl acetate, and n-butyl acetate; ethers such as diisopropyl ether, dimethoxy ethane, tetrahydrofuran, dioxyolan, and dioxane; amides such as N,N-dimethylformamide, N,N-dimethylacetamide, and N-methyl-2-pyrrolidone; halogenated hydrocarbons such as dichloromethane, chloroform, bromoform, methyl iodide, dichloroethane, trichloroethane, trichloroethylene, chlorobenzene, o-dichlorobenzene, fluorobenzene, bromobenzene, iodobenzene, and 1-chloronaphthalene; hydrocarbons such as n-pentane, n-hexane, n-octane, 1,5-hexadiene, cyclohexane, methylcyclohexane, cyclohexadiene, benzene, toluene, o-xylene, m-xylene, p-xylene, ethyl benzene, and cumene; and the like. These solvents can be used alone or in combination.

Specific examples of electrolytes for use as the hole transport material include combination of iodine (I₂) and a metal iodide or an organic iodide; combination of bromine (Br₂) and a metal bromide or an organic bromide; metal complexes such as ferrocyanic acid salt-ferricyanic acid salt, and ferrocene-ferricinium ion; sulfur compounds such as sodium polysulfide, and alkylthiol-alkyldisulfide; viologen dyes, hydroquinone-quinine; and the like.

Specific examples of the metal of the metal compounds mentioned above include Li, Na, K, Mg, Ca and Cs, but are not limited thereto. Specific examples of the cation of the organic compounds mentioned above include cations of quaternary ammoniums such as tetraalkylammoniums, pyridiniums, and imidazoliums, but are not limited thereto. These metals and cations can be used alone or in combination.

Among these electrolytes, combinations of I₂ and LiI, and combinations of NaI and a quaternary ammonium compound such as imidazolium iodide are preferably used.

When an electrolyte is used while dissolved in a solvent, the concentration of the electrolyte in the solution is preferably from 0.05M to 10M, and more preferably from 0.2M to 3M. The concentration of I₂ or Br₂ is preferably from 0.0005M to 1M, and more preferably from 0.001M to 0.5M.

In addition, in order to enhance the properties of the photoelectric converter such as open-circuit voltage and short-circuit current, additives such as 4-tert-butylpyridine and benzimidazolium can be added to the electrolyte.

Specific examples of the solvent constituting the electrolyte include water, alcohols, ethers, esters, carbonates, lactones, carboxylates, phosphoric trimesters, heterocyclic compounds, nitriles, ketones, amides, nitromethane, halogenated hydrocarbons, dimethylsulfoxide, sulfolane, N-methylpyrrolidone, 1,3-dimethylimidazolidinone, 3-methyloxazolidine, and hydrocarbons, but are not limited thereto. These materials can be used alone or in combination. In addition, ionic liquids (at room temperature) such as quaternary ammonium salts of tetraalkyls, pyridiniums, and imidazolium can also be used as the solvent.

Next, the metal oxide layer 11 will be described.

The metal oxide layer 11 is optionally formed between the hole transport layer 9-2 and the second electrode 33. Specific examples of the metal oxide constituting the metal oxide layer 11 include molybdenum oxide, tungsten oxide, vanadium oxide, and nickel oxide. Among these metal oxides, molybdenum oxide is preferable.

The method for preparing the metal oxide layer 11 is not particularly limited, and any known methods such as vacuum thin film forming methods (e.g., sputtering), and wet film forming methods can be used. In view of manufacturing costs, wet film forming methods are preferable. For example, a method including dispersing a powder or sol of a metal oxide in a medium to prepare a paste of the metal oxide, and then applying the paste on the hole transport layer using a known coating method such as dip coating, spray coating, wire bar coating, spin coating, roller coating, blade coating, and gravure coating, or a known printing method such as relief printing, offset printing, gravure printing, intaglio printing, rubber plate printing, and screen printing.

The thickness of the metal oxide layer 11 is preferably from 0.1 nm to 50 nm, and more preferably from 1 nm to 10 nm.

Next, the second electrode 33 will be described.

The second electrode 33, which serves as a hole collecting electrode, is formed on the hole transport layer 9-2 or the metal oxide layer 11.

The material mentioned above for use in the electron collecting electrode 3 can also be used for the second electrode 33. If the second electrode 33 has sufficient strength and sealing ability, a substrate supporting the second electrode is not necessarily used.

Specific examples of the materials for use in the second electrode 33 include metals such as platinum, gold, silver, copper, and aluminum, carbon compounds such as graphite, fullerene, and carbon nanotube, electroconductive metal oxides such as ITO and FTO, and electroconductive polymers such as polythiophene, and polyaniline. These materials can be used alone or in combination.

The thickness of the second electrode 33 is not particularly limited.

The method for preparing the second electrode 33 is determined depending on the materials used for the second electrode and the lower layer (such as hole transport layer 9-2), and methods such as coating, laminating, vapor deposition, and CVD can be used.

In order that this example can serve as a photoelectric converter, at least one of the first electrode (electron collecting electrode) 3 and the second electrode (hole collecting electrode) 33 has to be substantially transparent.

It is preferable for this example of the photoelectric converter of this disclosure that the first electrode 3 is transparent and light enters from the first electrode side. In this case, it is preferable to use a material capable of reflecting light for the second electrode 33. Specific examples of the light reflecting material include glass or plastics on which a metal layer or an electroconductive oxide layer is formed by evaporation, metal thin films, and the like.

In addition, it is preferable to form an antireflection layer is formed on the side of the photoelectric converter from which light enters.

An object of this disclosure is to provide a polylinker by which a thin solar cell can be produced at a relatively low temperature. Specifically, by using such a polylinker, a solar cell can be formed on a flexible substrate, which is made of a material sensitive to heat such as polymers.

In addition, another object of this disclosure is to provide a solar cell which can be easily prepared by a continuous preparation method, and a method for preparing a solar cell. For example, a roll-to-roll method can be used for preparing a solar cell instead of conventional batch methods. Specifically, this disclosure provides a method in which nano-sized particles of a metal oxide in a DSSC can be connected with each other by a polylinker without heating or by heating at a relatively low temperature. For example, by contacting nano-sized metal oxide particles with a polylinker, which is dispersed in a solvent such as n-butanol, at room temperature or a temperature lower than 300° C., the nano-sized particles can be connected with each other.

In this disclosure, an electrolyte composition is provided, and a method for preparing a solid or solid-like electrolyte is also provided. In this regard, the electrolyte composition, the solid electrolyte and the solid-like electrolyte correspond to the hole transport material mentioned above.

Replacing a liquid electrolyte with a solid or solid-like electrolyte makes it possible to prepare a flexible solar cell using a continuous preparation method such as roll-to-roll methods and web methods. In addition, gel electrolytes also solve the electrolyte leaking problem, thereby imparting good durability to DSSC. Further, this disclosure provides a method or a material for allowing a liquid electrolyte to gelate at room temperature or a relatively low temperature of lower than 300° C., thereby making it possible to produce a flexible solar cell at a relatively low temperature.

The gel electrolyte for use in this disclosure includes a redox-active component, and a polymer or a non-polymer with a small amount of plural ligands, which has been allowed to gelate by a metal ion complex forming method. In addition, an organic compound capable of forming a complex with a metal ion at multiple sites (for example, due to presence of a bound group) can be preferably used. In this regard, the redox-active component may be a liquid or a solid dissolved in a liquid solvent. The bound group represents a group including at least one donor atom having a high electron density such as O, N, S and P(III). The multiple bound groups can be present in a side chain or a main chain of the polymer or non-polymer. Alternatively, the bound groups can be present as a part of a dendrimer or a starburst compound.

By incorporating a metal ion (particularly lithium ion) into a liquid inorganic electrolyte composition, the properties of the photoelectric converter (solar cell) such as photocurrent, and open-circuit voltage can be improved, thereby enhancing the conversion efficiency of the solar cell.

In addition, this disclosure also provides a method for incorporating an electrolyte, a gelation compound, and a compound including a gel electrolyte and lithium in a solar cell.

This disclosure provides a composition and a method for satisfactorily adhering a solar cell to a substrate even at a relatively low temperature of lower than 300° C. By using such a composition or a method, a flexible thin solar cell can be produced at low costs using a continuous preparation method.

This disclosure also provides an oxide semiconductor coating liquid which includes an oxide semiconductor such as nano-sized dyed metal oxide particles and which can be applied on a flexible and transparent substrate at room temperature. Specifically, a nano-sized titania is provided which has a good mechanical stability and which can be satisfactorily adhered to a flexible and transparent substrate or a surface of a substrate, on which an electroconductive material layer is formed, even after the coated liquid is dried at a temperature of from about 50° C. to about 150° C. By using such a titania, a flexible thin solar cell can be produced by a continuous preparation method.

This disclosure also provides a co-sensitizer capable of enhancing the performance of a sensitizing dye. Such a co-sensitizer is adsorbed on the surface of nano-sized oxide semiconductor particles, which are connected with each other, together with a sensitizing dye. Such a co-sensitizer reduces chance of reverse transportation of electrons from the nano-sized oxide semiconductor particles to the sensitizing dye, thereby enhancing the conversion efficiency of the solar cell by about 17%. The co-sensitizer is a material which includes an aromatic amine compound, a carbazole compound, or a compound having a condensed ring and which has an ability of donating electrons to an acceptor while stably forming a cation radical.

Thus, this disclosure provides a method for connecting nano-sized particles with each other at a relatively low temperature, which includes preparing a solution including a solvent and a polylinker, and contacting nano-sized metal oxide particles with the solution at a relatively low temperature of lower than about 300° C., preferably lower than 200° C., more preferably lower than 200° C., and even more preferably room temperature. In this regard, the solution includes the polylinker in an amount sufficient for connecting at least part of the nano-sized metal oxide particles. The polylinker preferably includes a large molecule having a long chain, which preferably has substantially the same structure as the nano-sized metal oxide particles in the main chain thereof and which has at least one reactive group in the main chain. The nano-sized metal oxide particles preferably have a formula MxOy, wherein each of x and y represents an integer. Specific examples of the metal M include Ti, Zr, W, Nb, Ta, Tb, Mo and Sn.

The polylinker is preferably poly(n-butyltitanate), and the solvent is preferably n-butanol.

The mechanism of connecting at least part of nano-sized metal oxide particles is a physical or electrical bridge formed by at least one reactive group connected with the metal oxide particles. The metal oxide particles are preferably arranged as a thin film on a substrate, for example, by a dipping method in which a substrate is dipped into a solution including metal oxide particles and a polylinker, a spraying method in which a solution including metal oxide particles and a polylinker is sprayed on a substrate, or a coating method in which a solution including metal oxide particles and a polylinker is applied on a substrate. Alternatively, a method in which nano-sized metal oxide particles are applied on a substrate and then a solution including a polylinker is applied thereon can also be used.

In addition, the preparation method can include a step of contacting nano-sized metal oxide particles with a modifying solution.

The nano-sized metal oxide particles are preferably titanium oxide, zirconium oxide, zinc oxide, tungsten oxide, niobium oxide, lanthanum oxide, tantalum oxide, tin oxide, terbium oxide, or a combination of two or more of these metal oxides.

The present invention provides a polylinker solution including (1) a polylinker having a formula —[O-M(OR)i-]m-, (2) nano-sized metal oxide particles having a formula MxOy, and (3) a solvent, wherein each of i, m, x, and y is a positive integer, M represents Ti, Zr, Sn, W, Nb, Ta, Mo or Tb, R represents an alkyl group, an alkenyl group, an alkynyl group, an aromatic group, or an acyl group.

The polylinker solution preferably includes the polylinker in an amount sufficient for connecting at least part of nano-sized metal oxide particles with each other at a temperature of lower than 300° C., and preferably lower than 100° C. The polylinker solution is preferably a 1 wt % n-butanol solution of poly(n-butyltitanate).

Another example of the photoelectric converter is a flexible solar cell in which nano-sized particles of a photosensitive material, which are connected with each other, and an electron transport material are sandwiched by first and second flexible and transparent substrates. The nano-sized photosensitive material particles are preferably connected with each other by a polylinker. The average particle diameter of the nano-sized photosensitive material particles is preferably from about 5 nm to about 80 nm. The nano-sized photosensitive material is preferably titanium dioxide, zirconium oxide, zinc oxide, tungsten oxide, niobium oxide, lanthanum oxide, tantalum oxide, tin oxide, terbium oxide, or a combination of two or more of these metal oxides. The nano-sized photosensitive material can include a photosensitive agent (dye) such as xanthine, cyanine, merocyanine, phthalocyanine, and pyrrole. The photosensitive agent can include a metal ion such as divalent or trivalent metal ions. In addition, the photosensitive agent can include a transition metal complex such as ruthenium complexes, osmium complexes, and iron complexes. The electron transport material is preferably a polymer electrolyte. This electron transport material has a light transmission of not less than about 60%.

At least one of the first and second flexible substrates includes a transparent substrate such as polyethylene terephthalate and polyethylene naphthalate. The flexible solar cell can have a layer having a catalytic activity between the first and second flexible substrates. In addition, the flexible solar cell can have a layer of an electroconductive material (such as indium tin oxide) located on at least one of the first and second flexible substrates.

This disclosure provides an electrolyte composition suitable for solar cells. The electrolyte includes a metal ion, and an organic compound capable of forming a complex with the metal ion at plural sites. The metal ion is preferably a lithium ion. Specific examples of the organic compound include poly(4-vinylpyridine), poly(2-vinylpyridine), polyethylene oxide, polyurethane, polyamide, and the like. These materials can be used alone or in combination. The electrolyte composition can include a gelation compound such as lithium salts having a formula LiX, wherein X represents an anion such as a halogen atom, a perchlorate group, a thiocyanate group, a trifluoromethylsulfonate group, and a hexafluorophosphate group. In addition, the electrolyte composition can include iodine at a concentration of about 0.05M.

This disclosure provides an electrolyte solution for use in preparing a solar cell. The electrolyte solution includes a compound having a formula MiXj, wherein each of i and j is a positive integer, X represents a monovalent or polyvalent anion such as a halogen atom, a perchlorate group, a thiocyanate group, a trifluoromethylsulfonate group, a hexafluorophosphate group, a sulfate group, a carbonate group, or a phosphate group, and M represents a monovalent or polyvalent metal cation such as Li, Cu, Ba, Zn, Ni, lanthanide metals, Co, Ca, Al, and Mg.

This disclosure also provides a solar cell in which nano-sized particles of a photosensitive material, which are connected with each other, and an electrolyte redox system are sandwiched by first and second light transmissive substrates. The electrolyte redox system preferably includes a gelation compound including a metal ion, a polymer capable of forming a complex with the metal ion at plural sites, and an electrolyte solution. The metal ion is preferably a lithium ion, and the electrolyte solution includes an ionic liquid including an imidazolium iodide based compound including iodine at a concentration of 0.05M, and a deactivating agent such as t-butylpyridine, methylbenzimidazole, or chemical species which have a pair of free electrons and which can be adsorbed on titania.

This disclosure provides a method for allowing an electrolyte solution to gelate, which can be used for preparing a DSSC. The method includes preparing an electrolyte solution, and adding a material capable of forming a complex at plural sites, and a metal ion capable of forming the complex at the sites to the electrolyte solution. The above-mentioned steps are performed at a temperature of lower than 50° C. and a normal pressure. The metal ion is preferably a lithium ion. The gelation speed can be controlled by changing the concentration of a counter ion in the electrolyte. In addition, by changing the anion, the gelation speed and gelation rate can be controlled. For example, even when the concentration of lithium ion is constant, an iodide can allow an electrolyte solution to gelate at a higher gelation rate than that in a case of using a chloride or thiocyanic acid.

In addition, this disclosure provides a method for reducing transfer of electrons to chemical species in the electrolyte in the solar cell of this disclosure. The method includes providing a solar cell portion including a sensitizing dye layer, providing an electrolyte solution including a compound capable of forming a complex at plural sites, and adding a compound MX in an amount sufficient for allowing the electrolyte solution to gelate, wherein M represents an alkali metal, and X represents an anion such as a halogenide group, a perchlorate group, a thiocyanate group, a trifluoromethylsulfonate group, a hexafluorophosphate group, and then incorporating the thus prepared gel electrolyte into the solar cell portion.

This disclosure also provides an electrolyte composition suitable for solar cells. The electrolyte composition includes an ionic liquid, which includes imidazolium iodide, in an amount of about 90% by weight, water in an amount of from 0 to 10% by weight, iodine at a concentration of 0.05M, and methylbenzimidazole. The imidazolium iodide based ionic liquid preferably includes butylmethylimidazolium iodide, propylmethylimidazolium iodide, hexylmethylimidazolium iodide, or a combination of two or more of these iodides. The electrolyte composition can include LiCl. The amount of LiCl is preferably from about 1% by weight to about 6% by weight. The electrolyte composition can include LiI. The amount of LiI is preferably from about 1% by weight to about 6% by weight.

This disclosure provides a method for forming a layer of a nano-sized semiconductor oxide on a substrate. The method includes providing a substrate, coating a surface of a substrate with a primer including a semiconductor oxide, and coating the primer layer with a suspension of a nano-sized semiconductor oxide at a temperature of lower than 300° C., preferably lower than 150° C., and more preferably room temperature. The primer layer is formed to improve adhesion of the nano-sized semiconductor oxide to the substrate. The primer layer can be a film of a semiconductor oxide (such as titanium dioxide) formed by a vacuum coating method. The primer layer can be a layer of a particulate semiconductor oxide including titanium dioxide or tin oxide. The primer layer can include a thin layer including a polylinker solution, wherein the polylinker is preferably a poly(titanium (IV) butoxide) or a macromolecule having a long chain. The substrate is preferably made of a flexible and light transmissive material. In addition, electroconductive materials such as indium tin oxide can be used for the substrate. Alternatively, flexible and light transmissive materials on which an electroconductive material layer is formed can be used for the substrate.

This disclosure also provides a solar cell including a first flexible and light transmissive substrate, a primer layer located on the substrate, a nano-sized photosensitive material layer which includes a suspension of nano-sized semiconductor oxide connected with each other and which is located on the primer layer, a charge transport material layer, and a second flexible and light transmissive substrate, wherein these layers are sandwiched by the first and second substrates. Specific examples of the nano-sized photosensitive material include titanium oxide, zirconium oxide, zinc oxide, tungsten oxide, niobium oxide, lanthanum oxide, tin oxide, terbium oxide, tantalum oxide, and a combination of two or more of these metal oxides. The primer layer can be a film of a semiconductor oxide (such as titanium dioxide) formed by a vacuum coating method. The primer layer can be a layer of a particulate semiconductor oxide including titanium dioxide or tin oxide. The primer layer can include a thin layer including a polylinker solution, wherein the polylinker is preferably a poly(titanium (IV) butoxide) or a macromolecule having a long chain. A layer of an electroconductive material such as indium tin oxide can be formed on the first substrate.

This disclosure provides a coating liquid for use in preparing a layer of a solar cell. The coating liquid includes a solvent, a nano-sized particulate material dispersed in the solvent, a polymer binder dissolved in the solvent. When the coating liquid is applied on a substrate, followed by drying, both the particulate material and the polymer binder are located on the substrate, thereby forming a nano-sized particle film having good mechanical stability on the substrate. The film can be formed at room temperature. The coating liquid can include acetic acid. In addition, the nano-sized particulate material is preferably nano-sized titanium oxide. The weight ratio (T/B) of the titanium oxide (T) to the binder resin (B) is from 0.1/100 to 20/100, and preferably from 1/100 to 10/100. The solvent includes water and/or an organic solvent. Specific examples of the polymer binder includes polyvinylpyrrolidone, polyethylene oxide, hydroxyethyl cellulose, ethyl cellulose, hydroxypropyl cellulose, and polyvinyl alcohol. In addition, the coating liquid can include a polylinker connecting the nano-sized particles with each other. The substrate is preferably made of a flexible and light transmissive material.

This disclosure provides a method for forming a layer of the solar cell. Specifically, the method includes dispersing a nano-sized particulate material in a solvent, dispersing a polymer binder in the nano-sized particulate material dispersion to prepare a coating liquid, and applying the coating liquid on a substrate to form a nano-sized particle film having good mechanical stability on the substrate. By using this method, a nano-sized particle film can be formed at room temperature. The method can further include drying the coated liquid at a temperature of from about 50° C. to about 150° C.

This disclosure also provides a flexible solar cell including (1) a charge transport material layer located between first and second flexible and light transmissive substrates, and (2) a layer located between the substrates and prepared by coating a coating liquid, in which a nano-sized particulate semiconductor oxide is dispersed in a solvent and a polymer binder is dissolved in the solvent. The nano-sized particulate material is preferably a nano-sized particulate material connected with each other by a polylinker. Specific examples of the nano-sized particulate material include titanium oxide, zirconium oxide, zinc oxide, tungsten oxide, niobium oxide, lanthanum oxide, tin oxide, terbium oxide, tantalum oxide, and a combination of two or more of these metal oxides. The nano-sized particulate material can include a photosensitive agent (dye) such as xanthine, cyanine, merocyanine, phthalocyanine, and pyrrole. The photosensitive agent can include a metal ion such as divalent or trivalent metal ions. In addition, the photosensitive agent can include a transition metal complex such as ruthenium complexes, osmium complexes, and iron complexes. The substrate is preferably made of polyethylene terephthalate. Specific examples of the polymer binder includes polyvinylpyrrolidone, polyethylene oxide, hydroxyethyl cellulose, ethyl cellulose, hydroxypropyl cellulose, and polyvinyl alcohol.

This disclosure provides a photosensitive material. The photosensitive material includes a sensitizing dye to accept electromagnetic energy, and a co-sensitizer having a coordinate bond group so as to co-adsorb on a surface of a nano-sized metal oxide layer together with the sensitizing dye. The sensitizing dye is preferably cis-bis(isothiocyanato)bis(2,2′-bipyridyl-4,4′-dicarboxyrato)-ruthenium (II). The co-sensitizer preferably includes an aromatic amine or carbazole. Specific examples thereof include diphenylaminobenzoic acid, 2,6-bis(4-benzoate)-4-(4-N,N′-diphenylamino)phenylpyridinecarboxylic acid, and N′,N-diphenylaminophenylpropionic acid. Specific examples of the coordinate bond group include carboxyl groups, phosphate groups, and chelate groups (such as oxime and alfa-ketoenolate). The added amount of the co-sensitizer is less than about 50% by mol, preferably from about 1% by mol to about 20% by mol, and more preferably from about 1% by mol to about 5% by mol, based on the sensitizing dye.

This disclosure provides a photosensitive nano-sized particulate material layer for use in a solar cell. The layer include a sensitizing dye to accept electromagnetic energy, a co-sensitizer having a coordinate bond group, a nano-sized particulate photosensitive material having a surface on which the sensitizing dye and the co-sensitizer are to be co-adsorbed. The nano-sized particulate photosensitive material is preferably a nano-sized semiconductor oxide.

This disclosure also provides a method for preparing a photosensitive nano-sized particulate material layer. The method includes providing a layer of a nano-sized particulate material in which particles are connected with each other, applying a sensitizing dye on the nano-sized particulate material layer, and co-adsorbing a co-sensitizer having a coordinate bond group on the surface of the nano-sized particulate material. The photosensitive nano-sized particulate material is preferably a nano-sized particulate semiconductor oxide.

The sensitizing dye is preferably cis-bis(isothiocyanato)bis(2,2′-bipyridyl-4,4′-dicarboxyrato)-ruthenium (II). The co-sensitizer preferably includes an aromatic amine or carbazole. Specific examples thereof include diphenylaminobenzoic acid, 2,6-bis(4-benzoate)-4-(4-N,N′-diphenylamino)phenylpyridinecarboxylic acid, and N′,N-diphenylaminophenylpropionic acid.

The added amount of the co-sensitizer is less than about 50% by mol, and preferably from about 1% by mol to about 20% by mol, based on the sensitizing dye.

This disclosure provides a flexible solar cell including (1) a nano-sized particulate photosensitive material in which particles thereof are connected with each other and which includes (i) a sensitizing dye to accept electromagnetic energy, and (ii) a co-sensitizer having a coordinate bond group, and (2) a charge transport material. Both the sensitizing dye and the co-sensitizer are adsorbed on a surface of the nano-sized particulate photosensitive material. The nano-sized particulate photosensitive material and the charge transport material are sandwiched by first and second flexible and light transmissive substrates. The particles of the nano-sized particulate photosensitive material are preferably connected with each other by a polylinker. The average particle diameter of the nano-sized particulate photosensitive material is preferably from about 10 nm to about 40 nm. Specific examples of the nano-sized particulate photosensitive material include titanium oxide, zirconium oxide, zinc oxide, tungsten oxide, niobium oxide, lanthanum oxide, tin oxide, terbium oxide, tantalum oxide, and a combination of two or more of these metal oxides. The charge transport material preferably includes a redox electrolyte or a polymer electrolyte. The charge transport material preferably has light transmission of not less than about 60% in visible region.

At least one of the first and second flexible substrates includes a transparent substrate such as polyethylene terephthalate and polyethylene naphthalate. The flexible solar cell can have a layer having a catalytic activity between the first and second soft substrates. The layer having a catalytic activity preferably includes platinum. In addition, the flexible solar cell can have a layer of an electroconductive material (such as indium tin oxide) located on at least one of the first and second flexible substrates.

Next, the photoelectric converter of this disclosure will be described in detail by reference to examples.

### A. Connection of Nano-Sized Particles

As mentioned above briefly, this disclosure provides a polylinker which makes it possible to produce a web-form solar cell at a relatively low sintering temperature (lower than about 300° C.). In general, the term “sintering” means a process in which a material is heated at a temperature of not lower than about 400° C. However, in this application, “sintering” means a process in which nano-sized particles are connected with each other at any temperature. In addition, this disclosure also provides a method for connecting nano-sized particles for use in a solar cell using a polylinker. Further, this disclosure also provides a low temperature sintering process which makes it possible to make a solar cell using a flexible polymer substrate. By using a flexible substrate, continuous manufacturing methods such as roll-to-roll and web methods can be used for preparing solar cells.

In this disclosure, the polylinker is used together with a nano-sized particulate material having a formula MxOy, wherein M represents Ti, Zr, W, Nb, La, Ta, Tb, or Sn, and each of x and y is a positive integer.

The polylinker has a chain similar to the structure of the nano-sized particulate metal oxide used while having a reactive group having a formula (OR)i, wherein R represents a hydrogen atom, an acetate group, an alkyl group, an alkenyl group, an alkynyl group, an aromatic group, or an acyl group, and i is a positive integer. Specific examples of the alkyl groups include ethyl, propyl, butyl and pentyl groups, but are not limited thereto. Specific examples of the alkenyl groups include ethenyl, propenyl, butenyl, and pentenyl groups, but are not limited thereto. Specific examples of the alkynyl groups include ethynyl, propynyl, butynyl, and pentynyl groups, but are not limited thereto. Specific examples of the aromatic groups include phenyl, and benzyl groups, but are not limited thereto. Specific examples of the acyl groups include acetyl and benzoyl groups, but are not limited thereto. In addition, a halogen atom such as chlorine, bromine and iodine atoms can be used instead of the reactive group (OR)i.

The polylinker preferably has a branched chain including two chains each having a formula -M-O-M-O-M-O— and reactive groups having formulae (OR)i and (OR)i+1, wherein R represents one of the atom or groups mentioned above, and i is a positive integer. The two chains have structures similar to the structure of the nano-sized particulate metal oxide used. Specifically, the polylinker has a structure having a formula -M(OR)i-O-(M(OR)i-O)n-M(OR)i+1-, wherein each of i and n is a positive integer.

A polylinker, which is a low concentration solution of only one polylinker, can crosslink a large number of nano-sized particles, thereby forming a network of the nano-sized particles. However, when the concentration of the polylinker solution is increased, the nano-sized particles are coated with the polylinker polymer. Since the polylinker polymer is flexible, the nano-sized particles thus coated with the polylinker polymer can form a thin film. Since the electric properties and structural properties of the polylinker polymer are similar to those of the nano-sized particles, the electric properties of the nano-sized particles coated with the polylinker polymer are substantially the same as those of the nano-sized particles themselves.

In this disclosure, flexible materials having a light transmission of not less than about 60% in visible region are preferably used for the substrate. Specific examples of the materials include polyethylene terephthalate (PET), polyimide, polyethylene naphthalate (PEN), polymer-like hydrocarbons, cellulose compounds, and combinations of these materials. A surface of PET and PEN can have a layer including one or more electroconductive metal oxides such as indium tin oxide (ITO), fluorine-doped tin oxide, tin oxide, and zinc oxide.

By using such a polylinker, nano-sized particles can be connected with each other at a relatively low temperature of much lower than 400° C., and generally less than about 300° C.

By performing the treatment at a temperature in the temperature range, materials, which are damaged at a temperature in a conventional high treatment temperature range, can be used for the flexible substrate. In this disclosure, nano-sized particles can be connected with each other at a temperature of lower than 300° C., or a temperature of lower than 100° C. Further, it is possible to perform the treatment using a polylinker at room temperature of from about 18° C. to 30° C. and normal pressure of about 760 mmHg.

The reactive group of the polylinker is connected with the substrate, the coated layer of the substrate, or the oxide layer of the substrate used by a covalent bond, an ionic bond and/or a hydrogen bond. Since the polylinker is reacted with the oxide layer on the substrate, the oxide layer (i.e., nano-sized particles) can be connected with the substrate via the polylinker.

In the photoelectric converter of this disclosure, nano-sized metal oxide particles are contacted with a polylinker dispersed or dissolved in a proper solvent at room temperature or below room temperature, or at a relatively high temperature of not higher than 300° C., so that the nano-sized metal oxide particles are connected with each other. The method of contacting the nano-sized metal oxide particles with the polylinker solution is not particularly limited, and any know methods can be used. For example, initially a film of nano-sized metal oxide particles is formed on a substrate, and then a polylinker solution is sprayed on the film. Alternatively, a method in which nano-sized metal oxide particles are dispersed in a polylinker solution, and the dispersion is applied on a substrate can be used. In this regard, micro fluidizing methods, attriting methods, and ball milling can be used for dispersing nano-sized metal oxide particles in a solvent. Further, a method in which initially a polylinker solution is applied on a substrate, and then a film of nano-sized metal oxide particles is formed thereon can also be used.

By using the method in which nano-sized metal oxide particles are dispersed in a polylinker solution, a film of nano-sized metal oxide particles connected with each other can be prepared by one step. Specific examples of the method for applying such a dispersion include printing methods such as screen printing and gravure printing. In the method in which initially a polylinker solution is applied on a substrate, and then a film of nano-sized metal oxide particles is formed thereon, the concentration of the polylinker in the solution is controlled such that the coated polylinker layer has a predetermined thickness. In addition, before forming a film of nano-sized metal oxide particles on the coated polylinker layer, part (excess) of the solvent may be removed from the coated polylinker layer.

The formula of the nano-sized particles is not limited to MxOy. For example, sulfides, selenides, and tellurides of metals such as Ti, Zr, La, Nb, Sn, Ta, Tb, Mo, and W can also be used Suitable materials for use as the nano-sized particles include TiO₂, SrTiO₃, CaTiO₃, ZrO₂, WO₃, La₂O₃, Nb₂O₃, SnO₂, sodium titanate, and potassium niobate.

The polylinker for use in the present invention can have one or more kinds of reactive groups. In the example mentioned above, the polylinker has one kind of reactive group, OR. However, the polylinker can have plural kinds of reactive groups such as OR, OR′, and OR″, wherein each of R, R′ and R″ represents a hydrogen atom, an alkyl group, an alkenyl group, an aromatic group, or an acyl group. Alternatively, the reactive group OR can be replaced with a halogen atom. For example, the polylinker can have a polymer unit having a formula such as —[O-M(OR)i(OR′)j-]-, and —[O-M(OR)i(OR′)j(OR″)k-]-, wherein each of i, j, and k is a positive integer.

In the present invention, a method in which initially a polylinker solution is applied on a substrate, and then nano-sided particles are applied thereon to form an electroconductive oxide layer can be used. Specifically, when titanium dioxide is used for the nano-sided particles, initially a polylinker solution including poly(n-butyltitanate) is dissolved in n-butanol, and the solution is applied on a substrate. In this regard, the concentration of the polylinker in the solution is controlled such that the coated polylinker layer has a predetermined thickness. Next, a film of nano-sized titanium dioxide is formed on the polylinker layer. In this case, a hydroxyl group on the surface of the titanium oxide particles is reacted with a butoxy group (or another alkoxyl group) of poly(n-butyltitanate), thereby connecting the nano-sized particles with each other and the substrate.

The flexible and light transmissive substrate preferably includes a polymer. Specific examples thereof include PET, polyimide, PEN, polymer-like hydrocarbons, cellulose compounds, and combinations of these materials. In addition, the substrate can include a material on which the solar cell can be prepared by a method such as roll-to-roll methods and web methods. The substrate may be colored, but is preferably colorless. The substrate has one or more flat surfaces, but can have a surface which is not substantially flat. For example, the substrate can have a curved or stepped surface, for example, to form a Frensnel lens. In addition, the surface of the substrate may be subjected to patterning.

In the photoelectric converter of this disclosure, an electroconductive material layer can be formed on one or both of the surfaces of the substrate. Suitable materials for use as the electroconductive material include materials having high light transmittance such as ITO, fluorine-doped oxides, tin oxide, and zinc oxide. The thickness of the electroconductive material layer is preferably from about 100 nm to about 500 nm, and more preferably from about 150 nm to about 300 nm. In addition, a wire or conductor can be connected with the electroconductive material layer to electrically connect the solar cell with an external load.

The nano-sized particles connected with each other can include one or more nano-sized particulate metal oxides, which preferably have an average particle diameter of from about 2 nm to about 100 nm, more preferably from about 10 nm to about 40 nm, and even more preferably about 20 nm.

Various kinds of photosensitizers can be applied to nano-sized particles so that the nano-sized particles are connected with each other. Such photosensitizers assist to convert incident light to electricity, thereby enhancing the solar cell effect. Such photosensitizers absorb incident light, and cause electronic excitation. Due to the energy of the excited electrons, the electrons are transferred from the excited level of the sensitizers to the conduction band of the nano-sized particles, thereby efficiently causing charge separation resulting in production of the solar cell effect. The electrons in the conduction band of the nano-sized particles are used for driving an external load electrically connected with the solar cell.

The photosensitizer is chemically or physically adsorbed on a surface or the entire surface of the nano-sized particles connected with each other. A suitable photosensitizer is selected in consideration of the photon absorbing ability, the free electron generating ability in the conduction band of the nano-sized particles connected with each other, an ability to form a complex with the nano-sized particles, and an ability to be adsorbed on the nano-sized particles. Suitable materials for use as the photosensitizer include materials, which have a functional group such as a carboxyl group and a hydroxyl group and which can form a chelate, for example, with the Ti(VI) site of TiO₂. Specific examples thereof include anthocyanin, porphyrin, phthalocyanine, merocyanine, cyanine, squarate, eosin, cis-bis(isothiocyanato)bis(2,2′-bipyridyl-4,4-dicarboxylato)ruthenium (II) (i.e., N3), tris(isthiocyanato)ruthenium (II)-2,2′;6′,2″-terpyridyl-4,4′,4″-tricarboxylic acid, cis-bis(isocyanate)bis(2,2′-bipyridyl-4,4-dicarboxylato)ruthenium (II)bis-tetrabutylamonium, cis-bis(isocyanate)bis(2,2′-bipyridyl-4,4-dicarboxylato)ruthenium (II)dichloride, and the like. These materials can be available from SOLARONIX SA.

The portion of the solar cell including a charge transport material is formed by forming a charge transport material layer in the solar cell, and/or by dispersing a charge transport material in the nano-sized particles for use in forming the nano-sized photosensitive particle layer. Any known materials which can accelerate charge transport of from a current source to the nano-sized photosensitive particle layer can be used as the charge transport material. Suitable materials for use as the charge transport material include solvent-based liquid electrolytes, polymer electrolytes, solid electrolytes, n-type or p-type charge transport materials (e.g., electroconductive polymers), and gel electrolytes. These materials will be described below in detail.

Other materials can be used for the charge transport material. For example, lithium salts having a formula LiX can be used, wherein X represents iodide, bromide, chloride, perchlorate, thiocyanide, trifluoromethylsulfonate, or hexafluorophosphate. The charge transport material preferably includes a redox system such as organic redox systems and/or inorganic redox systems. Specific examples of the redox system include cerium(III)sulfide/cerium(IV), sodium bromide/bromine, lithium iodide/iodine, Fe²⁺/Fe, Co²⁺/Co³⁺, and viologen, but are not limited thereto. In addition, the electrolyte solution includes MiXj, wherein each of i and j is a positive integer, X represents an anion, and M represents Li, Cu, Ba, Zn, Ni, lanthanide, Co, Ca, Al, or Mg. Specific examples of the group X (anion) include chloride, perchlorate, thiocyanide, trifluoromethylsulfonate, or hexafluorophosphate.

The charge transport material preferably includes a polymer electrolyte such as combinations of poly(vinylimidazolium halogenide) and lithium iodide, and poly(vinylpyridinium salt). Alternatively, the charge transport material includes a solid electrolyte such as lithium iodide, pyridinium iodide, and substituted imidazolium iodide.

In addition, the charge transport material can include a polymer electrolyte composition including a polymer (such as ion-conducting polymer), a plasticizer, and a redox electrolyte (such as combinations of an organic or inorganic iodide and iodine). The content of the polymer is from about 5% by weight to about 100% by weight, preferably from 5% to 60%, more preferably 5% to 40%, and even more preferably from 5% to 20%. The content of the plasticizer is from about 5% by weight to about 95% by weight, preferably from 35% to 95%, more preferably 60% to 95%, and even more preferably from 80% to 95%. The concentration of the redox electrolyte is from about 0.05M to about 10M, wherein the concentration of an organic or inorganic iodide is from 0.05M to 10M, preferably from 0.05M to 2M, and more preferably from 0.05M to 0.5M, and the concentration of iodine is from 0.01M to 10M, preferably from 0.05M to 5M, more preferably from 0.05M to 2M, and even more preferably from 0.05M to 1M. Specific examples of the ion-conducting polymer include polyethylene oxide (PEO), polyacrylonitrile (PAN), polymethyl methacrylate (PMMA), polyether, and polyphenol. Specific examples of the plasticizer include ethyl carbonate, propylene carbonate, mixtures of carbonates, organic phosphates, butyrolactone, and dialkylphthalate.

The flexible solar cell of this disclosure can include a layer having a catalytic activity, which is located between substrates. The layer having a catalytic activity is electrically connected with a charge transport material in the solar cell. The layer having a catalytic activity includes ruthenium, osmium, cobalt, rhodium, iridium, nickel, activated carbon, palladium, platinum, or a hole transport polymer (such as poly(3,4-ethylenedioxythiophene) and polyaniline). More preferably, the layer further includes a metal such as titanium to improve adhesion of the layer to a substrate or a coated layer on a substrate. In this regard, the metal (such as titanium) forms a layer having a thickness on the order of about 10 Angstroms. Alternatively, the layer can include a platinum layer having a thickness of from about 13 Angstroms to about 50 Angstroms, and preferably about 25 Angstroms.

When a layer of nano-sized photosensitive particles is formed, a method in which a coating liquid including a polylinker solution and a nano-sized particulate metal oxide is applied on a moving substrate sheet can be used. The coating method is not particularly limited, and for example, dip coating, extrusion coating, spray coating, screen printing, and gravure printing can be used therefor. Alternatively, a method in which initially a polylinker solution is applied on a moving substrate sheet, and then a nano-sized particulate metal oxide is applied thereon can also be used. Further, a method in which initially a polylinker solution is applied on a moving substrate sheet, and then a nano-sized particulate metal oxide dispersed in a solvent is applied thereon can also be used. Furthermore, a method in which initially a nano-sized particulate metal oxide (preferably dispersed in a solvent) is applied on moving substrate sheet, and then a polylinker solution is applied thereon can also be used.

After a photosensitive nano-matrix material is prepared on a substrate, the substrate can be further subjected to a treatment. Specifically, a charge transport material to accelerate charge transport of from a current source to the photosensitive nano-sized particulate material is applied thereon. Specific examples of the application method include spray coating, roller coating, knife coating, and blade coating. The charge transport material is typically prepared by using a solution including an ion-conducting polymer, a plastiizer, and a mixture of an iodide and iodine. The polymer imparts mechanical stability or dimensional stability to the layer, the plasticizer contributes to gel/liquid phase transition temperature, and the mixture of an iodide and iodine serves as a redox electrolyte.

Next, the first and second insulating layers 24 and 25 will be described.

The material of the first and second insulating layers 24 and 25 is not particularly limited as long as the material is porous. Suitable materials for use in the insulating layers, include materials having a good combination of insulating property, durability and film formability such as materials including ZnS. ZnS has an advantage such that a layer can be rapidly formed by sputtering without damaging an electron transport layer. Specific examples of the materials including ZnS include ZnS—SiO₂, ZnS—SiC, ZnS—Si, and ZnS—Ge. The content of ZnS in the materials including ZnS is preferably from about 50% by mol to about 90% by mol so that the ZnS maintains crystallinity in the resultant insulating layer. Among these materials, ZnS—SiO₂ (8/2), ZnS—SiO₂ (7/3), ZnS, ZnS—ZnO—In₂O₃—Ga₂O₃ (60/23/10/7) are more preferable.

By using such materials for the insulating layers, the insulating layers have good insulating properties even when the layers are thin. Therefore, even when multiple insulating layers are overlaid, deterioration of the strength of the layers can be prevented (i.e., peeling of the layers can be avoided).

A porous insulating layer can be prepared, for example, by forming an insulating film consisting of a particulate material. Specifically, when a ZnS insulating layer is prepared by sputtering, a porous insulating layer can be prepared, for example, by forming the ZnS insulating layer on a granular undercoat layer. In this case, metal oxides can be used for the granular undercoat layer, but insulating particles such as silica and alumina can be preferably used.

By forming such a porous insulating layer, the electrolyte in the charge transport layer can penetrates the insulating layer.

The thickness of the insulating layer is preferably from 20 nm to 500 nm, and more preferably from 50 nm to 150 nm. When the insulating layer is too thin, the insulating layer has insufficient insulating property. In contrast, when the insulating layer is too thick, the manufacturing costs increase.

Next, the intermediate electrodes 22 and 23 will be described.

The materials mentioned above for use in the electron collecting electrode 3 can also be used for the first and second intermediate electrodes 22 and 23. When the material used for the intermediate electrodes has good strength and sealing ability, the electrodes do not necessarily have a substrate.

Specific examples of the materials for use in the intermediate electrodes 22 and 23 include metals such as platinum, gold, silver, copper, and aluminum, carbon compounds such as graphite, fullerene, and carbon nanotube, electroconductive metal oxides such as ITO and FTO, and electroconductive polymers such as polythiophene, and polyaniline. These materials can be used alone or in combination.

The thickness of the intermediate electrodes is not particularly limited.

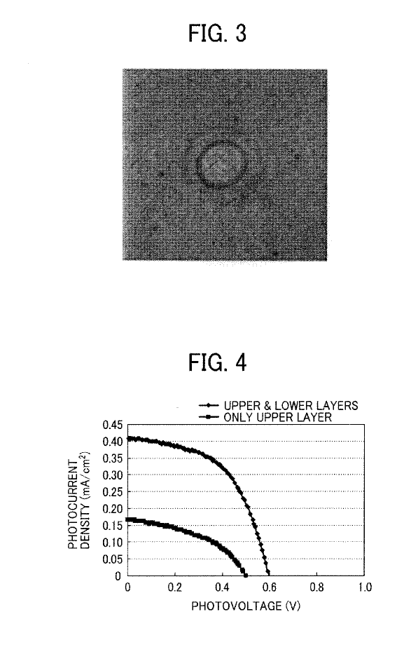

The intermediate electrodes have voids in which a hole transport material is contained. FIG. 3 is a photograph of a surface of an intermediate electrode taken by an optical microscope. Specifically, FIG. 3 is a photograph of a void present on a surface of an intermediate electrode. The void has a size (width) of from 0.5 μm to 500 μm. However, there are voids in the intermediate electrode, which cannot be observed by an optical microscope. The size of such small voids is from 50 nm to 500 nm.

The intermediate electrodes having voids can transmit holes and light. Since light proceeds while scattering in a TiO₂ layer (i.e., light cannot proceed straight), the transmittance cannot be measured.

Hereinafter, the photoelectric converter of this disclosure will be described by reference to examples of DSSC including a nano-sized particulate TiO₂. The nano-sized particulate material is not limited to TiO₂, and for example, SrTiO₃, CaTiO₃, ZrO₂, La₂O₃, Nb₂O₅, sodium titanate, potassium niobate, and the like can also be used. In addition, the photoelectric converter of this disclosure is not limited to DSSC. Therefore, metal oxides and semiconductor coating, in which nano-sized particles are connected with each other, can also be applied to the photoelectric converter so that the resultant photoelectric converter can be used for devices other than DSSC.

The photoelectric converter of this disclosure can be used for solar cells, power supplies using a solar cell, devices using such a power supply. For example, the photoelectric converter of this disclosure can be used for a solar cell for use in electronic calculators, and watches. In addition, the photoelectric converter of this disclosure can be preferably used for a power supply for use in cellular phones, electronic organizers, and electronic papers. Further, the photoelectric converter of this disclosure can also be used for an auxiliary power supply to prolong the usage time of a rechargeable battery or a battery in electric devices.

Having generally described this invention, further understanding can be obtained by reference to certain specific examples which are provided herein for the purpose of illustration only and are not intended to be limiting. In the descriptions in the following examples, the numbers represent weight ratios in parts, unless otherwise specified.

### EXAMPLES

### Example 1

A DSSC was prepared as follows.

Initially, a glass plate with a thickness of 1 mm, a surface of which was coated with a material SnO₂:F serving as the first electrode, was provided. When the resistance between two terminals of the first electrode was measured to determine the sheet resistance thereof, the sheet resistance was about 20Ω.

Next, a nano-sized titanium oxide dispersion (SP210 from Showa Titanium Co., Ltd.) was applied on the first electrode by spin coating, followed by annealing for 15 minutes at 120° C. Thus, a titanium oxide particle layer serving as an electron transport layer was prepared.

Further, an ethanol solution of a dye D131 having the below-mentioned formula (3) was applied on the titanium oxide particle layer by spin coating, followed by annealing for 10 minutes at 120° C. Thus, a first photoelectric conversion layer including the titanium oxide particle layer and the dye D131 was prepared.

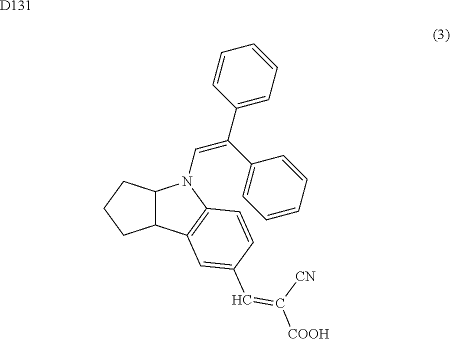

Next, a layer of ZnS—SiO₂ (8/2 by mol) having a thickness of from 25 to 150 nm (in this case, about 34 nm) was prepared on the first photoelectric conversion layer by sputtering. Thus, an inorganic insulating layer was formed.

Further, an ITO layer having a thickness of about 100 nm was formed on an area (with a size of 10 mm×20 mm) of the surface of the inorganic insulating layer, resulting in formation of a second electrode (i.e., an electroconductive material layer). The sheet resistance of the second electrode, which is determined by measuring resistance between two terminals set on the second electrode, was about 10Ω to about 200Ω.

Next, a nano-sized titanium oxide dispersion (SP210 from Showa Titanium Co., Ltd.) was applied on the second electrode by spin coating, followed by annealing for 15 minutes at 120° C. Thus, a titanium oxide particle layer serving as an electron transport layer was formed on the second electrode.

Further, a coating liquid in which a 1% by weight dye solution prepared by dissolving a dye Y7-19 having the below-mentioned formula (4) in 2,2,3,3-tetrafluoropropanol was mixed with the titanium oxide dispersion SP210 mentioned above in a weight ratio of 2.4/4 was applied on the titanium oxide particle layer by spin coating. Thus, a second photoelectric conversion layer including titanium oxide particles and the sensitizing dye was prepared.

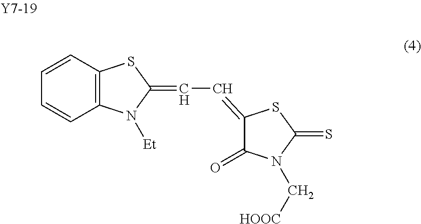

Next, an opposite electrode was prepared.

A transparent electroconductive layer of tin oxide was formed on one surface of a glass substrate of 10 mm×20 mm. In addition, a thermosetting electroconductive carbon ink CH10 from Jujo Chemical Co., Ltd. and 2-ethoxyethyl acetate were mixed in a ratio of 1:0.25 to prepare a coating liquid. The coating liquid was applied on the above-prepared transparent electroconductive layer by spin coating, followed by annealing for 15 minutes at 120° C. Thus, an opposite electrode was prepared. The opposite electrode was adhered to the second photoelectric conversion layer.

The following components were mixed to prepare a solution of an electrolyte composition (hole transport material).

| | | |
|---|---|---|
| Methoxyacetonitrile | 2 | g |
| Sodium iodide | 0.030 | g |
| 1-Propyl-2,3-dimethylimidazoliumiodide | 1.0 | g |
| Iodine | 0.10 | g |
| 4-Tert-butylpyridine | 0.054 | g |

The thus prepared electrolyte composition solution was injected into the device sandwiched by the substrates from an inlet thereof (located in the vicinity of the first electrode) using a pump while depressurizing to remove air bubbles from the device, and the inlet was sealed with an ionomer film, an acrylic resin and a glass plate. Thus, a dye sensitized photoelectric converter (i.e., DSSC) was prepared.

The DSSC was evaluated using a sunlight simulator at a light intensity of 1,000 W/m². The evaluation items were as follows.

1. IV curve & Average sunlight conversion rate η
2. Average open-circuit voltage Voc
3. Average short-circuit current Jsc
4. Average fill factor ff

The evaluation results are shown in Table 1 below.

TABLE 1

| Sample | Voc (V) | Jsc (mA/cm²) | ff | η (%) |
|---|---|---|---|---|
| Tandem (upper | 0.603 | 0.408 | 0.524 | 0.129 |
| and lower layers) | | | | |
| Tandem (only | 0.508 | 0.167 | 0.436 | 0.037 |
| upper layer) | | | | |

In this DSSC, parallel connection was made. Although the upper layer has a relatively small average short-circuit current Jsc of 0.167, the tandem (upper and lower layers) can have a large average short-circuit current Jsc (0.408).

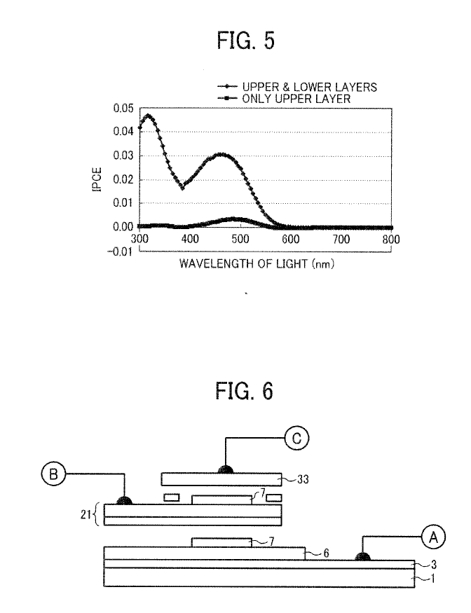

It can be understood from FIGS. 4 and 5 that the dyes included in the upper and lower layers function independently.

### Example 2

A glass plate with a thickness of 1 mm coated with SnO₂:F (first electrode) was provided.

Next, a nano-sized titanium oxide dispersion (T20 from SOLARONIX SA) was applied on the first electrode by a printing method, followed by annealing for 30 minutes at 550° C. Thus, a titanium oxide particle layer with a thickness of 9 μm was prepared.

In addition, a solution SNOW LATEX MIBK-SZC from Nissan Chemical industries Ltd., which includes silica as a solid component, methyl isobutyl ketone, and methanol at a weight ratio of 45%, 50% and 5%, was applied on the above-prepared titanium oxide particle layer by spin coating at a revolution of 2500 rpm.

Further, the following components were mixed to prepare a coating liquid.

| | | |
|---|---|---|
| SNOW LATEX MEK-2040 | 1 | part |
| (silica, from Nissan Chemical industries Ltd.) | | |
| Aqueous urethane resin | 5 | parts |
| (HW-140SF from Dainippon Ink and Chemicals Inc.) | | |
| 2,2,3,3-tetrafluoropropanol | 95 | parts |
| (from Daikin Industries, Ltd.) | | |

The coating liquid was applied on the above-prepared titanium oxide particle layer by spin coating at a revolution of 2,500 rpm.

Further, a ZnS/SiO₂ layer with a thickness of 34 nm was formed on the above-prepared layer by sputtering, and an ITO layer with a thickness of 77 nm was formed thereon by sputtering.

Furthermore, the nano-sized titanium oxide dispersion (T20 from SOLARONIX SA) was applied on the layer by a printing method, followed by annealing for 30 minutes at 550° C. Thus, a titanium oxide particle layer with a thickness of 3.1 μm was prepared.

The thus prepared cell was dipped into an ethanol solution of a dye having the above-mentioned formula (I) for 1 hour at 60° C.

Thereafter, the cell was washed with ethanol to remove excessive dye therefrom, followed by annealing for 3 minutes at 120° C. to remove the solvent therefrom.

The following components were mixed to prepare a solution of an electrolyte composition (hole transport material).

| | | |
|---|---|---|
| Methoxyacetonitrile | 2 | g |
| Sodium iodide | 0.030 | g |
| 1-Propyl-2,3-dimethylimidazoliumiodide | 1.0 | g |
| Iodine | 0.10 | g |
| 4-Tert-butylpyridine | 0.054 | g |

The thus prepared electrolyte composition solution was injected into the device sandwiched by the substrates from an inlet thereof using a pump while depressurizing to remove air bubbles from the device, and the inlet was sealed with an ionomer film, an acrylic resin and a glass plate. Thus, a dye (D102) sensitized photoelectric converter (i.e., DSSC) of Example 2 was prepared.

The DSSC of Example 2 was evaluated by the method described above in Example 1.

The evaluation results are shown in Table 2 below.

TABLE 1

| | Connection | | | | |
|---|---|---|---|---|---|
| Sample | method | Voc (V) | Jsc (mA/cm²) | ff | η (%) |
| Example 2 | Electrode B − | 0.614 | 8.729 | 0.598 | 3.204 |
| | Electrode C | | | | |
| | (illustrated in | | | | |
| | FIG. 6) | | | | |
| | Electrode | 0.539 | 8.313 | 0.469 | 2.097 |
| | (A + B) − | | | | |
| | Electrode C | | | | |
| | Electrode A − | 0.624 | 8.529 | 0.594 | 3.159 |
| | Electrode C | | | | |

### Example 3

A glass plate with a thickness of 1 mm coated with SnO₂:F (first electrode) was provided.

A nano-sized titanium oxide dispersion was coated on the first electrode by spin coating to prepare a dense titanium oxide layer thereon.

Next, a nano-sized titanium oxide dispersion (T20 from SOLARONIX SA) was applied on the dense titanium oxide layer by a printing method, followed by annealing for 30 minutes at 550° C. Thus, a titanium oxide particle layer with a thickness of 9 μm was prepared.

In addition, a solution SNOW LATEX MIBK-SZC from Nissan Chemical industries Ltd., which includes silica as a solid component, methyl isobutyl ketone, and methanol at a weight ratio of 45%, 50% and 5%, was applied on the above-prepared titanium oxide particle layer by spin coating at a revolution of 2,500 rpm.

Further, the following components were mixed to prepare a coating liquid.

| | | |
|---|---|---|
| SNOW LATEX MEK-2040 | 1 | part |
| (silica, from Nissan Chemical industries Ltd.) | | |
| Aqueous urethane resin | 5 | parts |
| (HW-140SF from Dainippon Ink and Chemicals Inc.) | | |
| 2,2,3,3-tetrafluoropropanol | 95 | parts |
| (from Daikin Industries, Ltd.) | | |

The coating liquid was applied on the above-prepared titanium oxide particle layer by spin coating at a revolution of 2,500 rpm.

Further, a ZnS/SiO₂ layer with a thickness of 34 nm was formed on the above-prepared layer by sputtering, and an ITO layer with a thickness of 77 nm was formed thereon by sputtering.

Furthermore, the nano-sized titanium oxide dispersion (SP210 from Showa Titanium Co., Ltd.) was applied on the layer by spin coating, followed by annealing for 15 minutes at 120° C. Thus, a titanium oxide particle layer was prepared.

The thus prepared cell was dipped into an ethanol solution of a dye having the above-mentioned formula (I) for 1 hour at 60° C.

Thereafter, the cell was washed with ethanol to remove excessive dye therefrom, followed by annealing for 3 minutes at 120° C. to remove the solvent therefrom.

The following components were mixed to prepare a solution of an electrolyte composition (hole transport material).

| | | |
|---|---|---|
| Methoxyacetonitrile | 2 | g |
| Sodium iodide | 0.030 | g |
| 1-Propyl-2,3-dimethylimidazoliumiodide | 1.0 | g |
| Iodine | 0.10 | g |
| 4-Tert-butylpyridine | 0.054 | g |

The thus prepared electrolyte composition solution was injected into the device sandwiched by the substrates from an inlet thereof using a pump while depressurizing to remove air bubbles from the device, and the inlet was sealed with an ionomer film, an acrylic resin and a glass plate. Thus, a dye (D102) sensitized photoelectric converter (i.e., DSSC) of Example 3 was prepared.

The DSSC of Example 3 was also evaluated by the method described above in Example 1. As a result, the DSSC had substantially the same properties as the DSSC of Example 2.

### Example 4

A glass plate with a thickness of 1 mm coated with SnO₂:F (first electrode) was prepared.

Next, a titanium oxide paste, which was prepared as mentioned below, was applied on the first electrode to prepare a titanium oxide layer.

The titanium oxide paste was prepared as follows. Specifically, 125 ml of titanium isopropoxide was dropped into 750 ml of a 0.1M aqueous solution of nitric acid at room temperature while agitating the mixture. Thereafter the mixture was heated to 80° C. in a chamber while agitated. As a result, a semi-transparent clouded sol was obtained.

After the sol was cooled to room temperature, the sol was filtered with a glass filter, and the filtered sol was mixed with a solvent to increase the volume to 700 ml.

The sol was heated for 12 hours at 220° C. in an autoclave to perform a hydrothermal reaction, followed by a supersonic dispersing treatment for 1 hour.

Further, the sol was condensed at 40° C. using an evaporator so as to have a TiO₂ content of 20% by weight.

The condensed sol was mixed with polyethylene glycol in an amount of 20% by weight based on the weight of the titanium oxide included in the sol, and anatase-form titanium oxide having a particle diameter of 200 nm in an amount of 30% by weight based on the weight of the titanium oxide, and the mixture was agitated by an agitating deaerator. Thus, a titanium oxide paste dispersion was prepared.

The procedure for preparation and evaluation of the DSSC of Example 2 was repeated except that the first particulate electron transport layer was prepared using the titanium oxide paste dispersion. As a result, the DSSC had substantially the same properties as the DSSC of Example 2.

### Example 5

The procedure for preparation and evaluation of the DSSC of Example 1 was repeated except that the titanium oxide was replaced with zinc oxide. The resultant solar cell had a photoelectric conversion efficiency of 0.5%.

### Example 6

The procedure for preparation and evaluation of the DSSC of Example 1 was repeated except that the titanium oxide was replaced with tin oxide. The resultant solar cell had a photoelectric conversion efficiency of 0.31%.

### Example 7

The procedure for preparation and evaluation of the DSSC of Example 1 was repeated except that the dip coating method used for applying the dye solution was replaced with a method in which the dye solution is set at an edge of the electrode so that the dye solution penetrated the cell. The evaluation results of the solar cell are shown in Table 3 below.

TABLE 3

| Sample | Voc (V) | Jsc (mA/cm²) | ff | η (%) |
|---|---|---|---|---|
| Example 7 | 1 | 2.475 | 0.424669 | 1.051056 |
| (tandem) | | | | |

### Example 8

A glass plate with a thickness of 1 mm coated with SnO₂:F (first electrode) was provided.

Next, a nano-sized titanium oxide dispersion (T20 from SOLARONIX SA) was applied on the first electrode by a printing method, followed by annealing for 30 minutes at 550° C. Thus, a titanium oxide particle layer with a thickness of 9 μm was prepared.

In addition, a solution SNOW LATEX MIBK-SZC from Nissan Chemical industries Ltd., which includes silica as a solid component, methyl isobutyl ketone, and methanol at a weight ratio of 45%, 50% and 5%, was applied on the above-prepared titanium oxide particle layer by spin coating at a revolution of 2,500 rpm.

Further, the following components were mixed to prepare a coating liquid.

| | | |
|---|---|---|
| SNOW LATEX MEK-2040 | 1 | part |
| (silica, from Nissan Chemical industries Ltd.) | | |
| Aqueous urethane resin | 5 | parts |
| (HW-140SF from Dainippon Ink and Chemicals Inc.) | | |
| 2,2,3,3-tetrafluoropropanol | 95 | parts |
| (from Daikin Industries, Ltd.) | | |

The coating liquid was applied on the above-prepared titanium oxide particle layer by spin coating at a revolution of 2,500 rpm.

Further, a ZnS/SiO₂ layer with a thickness of 34 nm was formed on the above-prepared layer by sputtering, and an ITO layer with a thickness of 77 nm was formed thereon by sputtering.

Furthermore, the nano-sized titanium oxide dispersion (T20 from SOLARONIX SA) was applied on the layer by a printing method, followed by annealing for 30 minutes at 550° C.

Thus, a titanium oxide particle layer with a thickness of 3.1 μm was prepared.

In addition, a solution SNOW LATEX MIBK-SZC from Nissan Chemical industries Ltd., which includes silica as a solid component, methyl isobutyl ketone, and methanol at a weight ratio of 45%, 50% and 5%, was applied on the above-prepared titanium oxide particle layer by spin coating at a revolution of 2,500 rpm.

Further, the following components were mixed to prepare a coating liquid.

| | | |
|---|---|---|
| SNOW LATEX MEK-2040 | 1 | part |
| (silica, from Nissan Chemical industries Ltd.) | | |
| Aqueous urethane resin | 5 | parts |
| (HW-140SF from Dainippon Ink and Chemicals Inc.) | | |
| 2,2,3,3-tetrafluoropropanol | 95 | parts |
| (from Daikin Industries, Ltd.) | | |

The coating liquid was applied on the above-prepared titanium oxide particle layer by spin coating at a revolution of 2,500 rpm.

Further, a ZnS/SiO₂ layer with a thickness of 34 nm was formed on the above-prepared layer by sputtering, and an ITO layer with a thickness of 77 nm was formed thereon by sputtering.

Furthermore, the nano-sized titanium oxide dispersion (T20 from SOLARONIX SA) was applied on the layer by a printing method, followed by annealing for 30 minutes at 550° C. Thus, a titanium oxide particle layer with a thickness of 3.1 μm was prepared.

The thus prepared cell was dipped into an ethanol solution of a dye having the above-mentioned formula (I) for 1 hour at 60° C.

Thereafter, the cell was washed with ethanol to remove excessive dye therefrom, followed by annealing for 3 minutes at 120° C. to remove the solvent therefrom.

The following components were mixed to prepare a solution of an electrolyte composition (hole transport material).

| | | |
|---|---|---|
| Methoxyacetonitrile | 2 | g |
| Sodium iodide | 0.030 | g |
| 1-Propyl-2,3-dimethylimidazoliumiodide | 1.0 | g |
| Iodine | 0.10 | g |
| 4-Tert-butylpyridine | 0.054 | g |

The thus prepared electrolyte composition solution was injected into the device sandwiched by the substrates from an inlet thereof using a pump while depressurizing to remove air bubbles from the device, and the inlet was sealed with an ionomer film, an acrylic resin and a glass plate. Thus, a dye sensitized photoelectric converter (i.e., DSSC) of Example 8 was prepared.

The DSSC of Example 8 was evaluated by the method described above in Example 1. As a result, it was confirmed that the DSSC can perform photoelectric conversion.

### Example 9

Initially, a glass plate with a thickness of 1 mm, on a surface of which was coated with a material SnO₂:F serving as the first electrode, was provided. When the resistance between two terminals of the electrode was measured to determine the sheet resistance thereof, the sheet resistance was about 20Ω.

Next, a nano-sized titanium oxide dispersion (SP210 from Showa Titanium Co., Ltd.) was applied on the first electrode by spin coating, followed by annealing for 15 minutes at 120° C. Thus, a titanium oxide particle layer serving as an electron transport layer was prepared.

In addition, an ethanol solution of a dye D131 having the above-mentioned formula (3) was applied on the titanium oxide particle layer by spin coating, followed by annealing for 10 minutes at 120° C. Thus, a first photoelectric conversion layer including titanium oxide particles and the dye D131 was prepared.

Further, a ZnS/SiO₂ (8:2) layer with a thickness of from 25 nm to 150 nm (in this case, 34 nm) was formed on the above-prepared layer by sputtering to prepare an inorganic insulating layer.

Furthermore, an ITO layer having a thickness of about 100 nm was formed on an area (with a size of 10 mm×20 mm) of the surface of the inorganic insulating layer, resulting in formation of a second electrode (i.e., an electroconductive material layer. The sheet resistance of the second electrode, which is determined by measuring resistance between two terminals set on the second electrode, was about 10Ω to about 200Ω.

Next, a nano-sized titanium oxide dispersion (SP210 from Showa Titanium Co., Ltd.) was applied on the second electrode by spin coating, followed by annealing for 15 minutes at 120° C. Thus, a titanium oxide particle layer serving as an electron transport layer was formed on the second electrode.

In addition, a coating liquid in which a 1% by weight dye solution prepared by dissolving a dye Y7-19 having the above-mentioned formula (4) in 2,2,3,3-tetrafluoropropanol was mixed with the titanium oxide dispersion SP210 mentioned above in a weight ratio of 2.4/4 was applied on the titanium oxide particle layer by spin coating. Thus, a second photoelectric conversion layer including titanium oxide particles and the sensitizing dye was prepared.

Further, a ZnS/SiO₂ (8:2) layer with a thickness of from 25 nm to 150 nm (in this case, 34 nm) was formed on the above-prepared layer by sputtering to prepare an inorganic insulating layer.

Furthermore, an ITO layer having a thickness of about 100 nm was formed on an area (with a size of 10 mm×20 mm) of the surface of the inorganic insulating layer, resulting in formation of a third electrode (i.e., an electroconductive material layer). The sheet resistance of the third electrode, which is determined by measuring resistance between two terminals set on the third electrode, was about 10Ω to about 200Ω.

Next, a nano-sized titanium oxide dispersion (SP210 from Showa Titanium Co., Ltd.) was applied on the third electrode by spin coating, followed by annealing for 15 minutes at 120° C. Thus, a titanium oxide particle layer serving as an electron transport layer was formed on the third electrode.

In addition, a coating liquid in which a 1% by weight dye solution prepared by dissolving a dye D102 having the above-mentioned formula (I) in 2,2,3,3-tetrafluoropropanol was mixed with the titanium oxide dispersion SP210 mentioned above in a weight ratio of 2.4/4 was applied on the titanium oxide particle layer by spin coating. Thus, a third photoelectric conversion layer including titanium oxide particles and the sensitizing dye was prepared.

The opposite electrode was prepared as follows.

A transparent electroconductive layer of tin oxide was formed on one surface of a glass substrate of 10 mm×20 mm. In addition, a thermosetting electroconductive carbon ink CH10 from Jujo Chemical Co., Ltd. and 2-ethoxyethyl acetate were mixed in a ratio of 1:0.25 to prepare a coating liquid. The coating liquid was applied on the above-prepared transparent electroconductive layer by spin coating, followed by annealing for 15 minutes at 120° C. Thus, an opposite electrode was prepared.

The following components were mixed to prepare a solution of an electrolyte composition (hole transport material).

| | | |
|---|---|---|
| Methoxyacetonitrile | 2 | g |
| Sodium iodide | 0.030 | g |
| 1-Propyl-2,3-dimethylimidazoliumiodide | 1.0 | g |
| Iodine | 0.10 | g |
| 4-Tert-butylpyridine | 0.054 | g |

The thus prepared electrolyte composition solution was injected into the device sandwiched by the substrates from an inlet thereof using a pump while depressurizing to remove air bubbles from the device, and the inlet was sealed with an ionomer film, an acrylic resin and a glass plate. Thus, a dye sensitized photoelectric converter (i.e., DSSC) was prepared.

This DSSC has a configuration such that a layer of the DSSC located closer to the substrate absorbs light having a shorter wavelength.

The DSSC was also evaluated by the method described in Example 1. As a result, it was confirmed that the DSSC of Example 9 has a photoelectric conversion ability.

### Comparative Example 1

The procedure for preparation and evaluation of the DSSC in Example 2 was repeated except that the DSSC is a single-layer solar cell in which the single titanium oxide layer has a thickness of 9 μm whereas the DSSC of Example 2 is a tandem solar cell. In this regard, a modified version of the DSSC of Example 2, in which the thickness (9 μm) of the first titanium oxide particle layer was changed to 6.4 μm so that the total thickness of the titanium oxide layers becomes about 9 μm, was also prepared for comparison. The evaluation results of the DSSC of Comparative Example 1 are shown in Table 4 below.

TABLE 4

| Sample | Voc (V) | Jsc (mA/cm²) | ff | η (%) |
|---|---|---|---|---|
| Modified | 0.649 | 12.321 | 0.668 | 5.336 |
| version of DSSC | | | | |
| of Example 2 | | | | |
| (tandem) | | | | |
| Comparative | 0.664 | 11.283 | 0.659 | 4.938 |
| Example 1 | | | | |
| (single layer) | | | | |

It is clear from Table 4 that the tandem DSSC of this disclosure (i.e., modified DSSC of Example 2) has a higher photoelectric conversion efficiency than the single-layer DSSC of Comparative Example 1.

Additional modifications and variations of the present invention are possible in light of the above teachings. It is therefore to be understood that within the scope of the appended claims the invention may be practiced other than as specifically described herein.

What is claimed is:

1. A photoelectric converter comprising:
a substrate; and
multiple cells located on the substrate so as to be overlaid, wherein a first cell contacted with the substrate includes:
a transparent electrode located on the substrate; and
a first photoelectric conversion layer located on the transparent electrode, and the other of the multiple cells or each of the others of the multiple cells includes:
a porous electroconductive layer including an electroconductive material while having voids containing a hole transport material; and
a photoelectric conversion layer located on the porous electroconductive layer so as to be farther from the substrate than the porous electroconductive layer, and
wherein each of the photoelectric conversion layers of the multiple cells includes:
an electron transport layer including an electron transport material, a dye connected with or adsorbed on the electron transport material, and the hole transport material.

2. The photoelectric converter according to claim 1, wherein the dyes included in the multiple cells have different wavelengths of maximum absorption.

3. The photoelectric converter according to claim 2, wherein the dye included in one of the multiple cells has a shorter wavelength of maximum absorption as the cell becomes closer to the substrate.

4. The photoelectric converter according to claim 1, wherein the dyes included in the multiple cells have a same wavelength of absorption maximum.

5. The photoelectric converter according to claim 1, further comprising:
an insulating layer,
wherein in any two adjacent cells of the multiple cells, the electron transport layer of one of the adjacent two cells is separated from the porous electroconductive layer of the adjacent cell by the insulating layer, wherein a total thickness of the insulating layer and the porous electroconductive layer is less than a thickness of the electron transport layer.

6. The photoelectric converter according to claim 5, wherein the insulating layer includes a sulfide or an oxide, and is prepared by a vacuum film forming method.

7. The photoelectric converter according to claim 6, wherein the insulating layer includes ZnS.

8. The photoelectric converter according to claim 1, wherein the electron transport material includes an oxide semiconductor.

9. The photoelectric converter according to claim 8, wherein the oxide semiconductor includes at least one of Ti, Zn and Sn.

10. The photoelectric converter according to claim 1, wherein the electroconductive material includes at least one of In, Al and Sn.

11. The photoelectric converter according to claim 1, wherein each of the multiple cells has an inlet from which a liquid can be injected into the cell.

12. The photoelectric converter according to claim 1, wherein the first photoelectric conversion layer further includes:
an insulating layer including particulate SiO₂,
wherein the electron transport layer of the first photoelectric conversion layer includes dyed TiO₂, wherein the electron transport layer, the insulating layer, and the electroconductive layer are overlaid on the transparent electrode in this order, and wherein the electron transport layer of a second photoelectric conversion layer adjacent to the first photoelectric conversion layer includes dyed TiO₂, and is located on the electroconductive layer of the first photoelectric conversion layer.
